(19) United States
(12) Patent Application Publication
(10) Pub. No.: US 2026/0033391 A1
(43) Pub. Date: Jan. 29, 2026

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Manhee HAN, Suwon-si (KR); Jonggill LEE, Suwon-si (KR); Baekkyun JEONG, Suwon-si (KR); Sanghoon JUNG, Suwon-si (KR); Wongil HAN, Suwon-si (KR); Cheolsoo HAN, Suwon-si (KR)

(73) Assignee: Samsung Electronics Co., Ltd., Suwon-si (KR)

(21) Appl. No.: 19/082,405

(22) Filed: Mar. 18, 2025

(30) Foreign Application Priority Data
Jul. 24, 2024 (KR) 10-2024-0097813

(51) Int. Cl. H01L 25/065; H01L 21/56; H01L 23/00; H01L 23/538; H10B 80/00

(52) U.S. Cl. CPC H01L 25/0657; H01L 21/565; H01L 23/5383; H01L 24/16; H01L 24/32; H01L 24/45; H01L 24/48; H01L 24/73; H01L 24/81; H01L 24/85; H01L 2224/16145; H01L 2224/32145; H01L 2224/32225; H01L 2224/45124; H01L 2224/45144; H01L 2224/45147; H01L 2224/48145; H01L 2224/48227; H01L 2224/48464; H01L 2224/73207; H01L 2224/73253; H01L 2224/73265; H01L 2224/81011; H01L 2224/81801; H01L 2224/85186; H01L 2225/06506; H01L 2225/0651; H01L 2225/06513; H01L 2225/06562; H01L 2924/1436; H10B 80/00

(57) ABSTRACT

A semiconductor package may include a package substrate; first semiconductor chips sequentially stacked on an upper surface of the package substrate; a second semiconductor chip on an uppermost first semiconductor chip among the first semiconductor chips, the second semiconductor chip having an overhang region protruding from one side of the uppermost first semiconductor chip and an overlapping region overlapping the uppermost first semiconductor chip, the second chip pads including first bonding pads in the overhang region and second bonding pads in the overlapping region; first conductive bumps respectively on the first bonding pads; second conductive bumps respectively on the second bonding pads; vertical wires extending from the first conductive bumps to substrate pads of the package substrate, respectively; and a molding member covering the first semiconductor chips, the second semiconductor chip, and the vertical wires.

### PRIORITY STATEMENT

This application claims priority under 35 U.S.C. § 119 to Korean Patent Application No. 10-2024-0097813, filed on Jul. 24, 2024 in the Korean Intellectual Property Office (KIPO), the contents of which are herein incorporated by reference in their entirety.

### BACKGROUND

### 1. Field

Example embodiments relate to a semiconductor package and/or a method of manufacturing the semiconductor package. More particularly, example embodiments relate to a multi-chip package including a plurality of stacked chips and/or a method of manufacturing the same.

### 2. Description of the Related Art

In manufacturing a multi-chip package, a plurality of semiconductor chips may be stacked on a package substrate, and the semiconductor chips may be electrically connected to the package substrate using bonding wires. The bonding wires may extend outward from one surface of the semiconductor chip and be bonded to substrate pads of the package substrate. Since the bonding wires may require a loop height, the bonding wires may increase the overall thickness of the package.

In addition, in manufacturing a semiconductor package using vertical wires, the vertical wires may be formed on chip pads of semiconductor chips that are sequentially stacked, a molding member may be formed to cover the semiconductor chips and the vertical wires, and a redistribution wiring layer may be formed on one surface of the molding member to be electrically connected to the vertical wires. Since process steps and equipment for a redistribution wiring process for forming the redistribution wiring layer are required, the manufacturing process may become more complicated and the production costs may increase.

### SUMMARY

Example embodiments provide a semiconductor package that is able to reduce the overall thickness, simplify the manufacturing process of the package, and/or improve reliability and productivity.

Example embodiments provide a method of manufacturing the semiconductor package.

According to example embodiments, a semiconductor package may include a package substrate; a plurality of first semiconductor chips sequentially stacked on an upper surface of the package substrate, each of the plurality of first semiconductor chips including a first surface and a second surface, the first surface including first chip pads and being opposite the second surface, the second surface facing the package substrate; a second semiconductor chip on an uppermost first semiconductor chip among the plurality of first semiconductor chips, a first surface of the second semiconductor chips including second chip pads and facing the package substrate, the second semiconductor chip having an overhang region protruding from one side of the uppermost first semiconductor chip and an overlapping region overlapping the uppermost first semiconductor chip, the second chip pads including a plurality of first bonding pads in the overhang region and a plurality of second bonding pads in the overlapping region; a plurality of first conductive bumps respectively on the plurality of first bonding pads of the second semiconductor chip; a plurality of second conductive bumps respectively on the plurality of second bonding pads of the second semiconductor chip, the plurality of second conductive bumps between the second semiconductor chip and the uppermost first semiconductor chip; a plurality of vertical wires extending from the plurality of first conductive bumps to substrate pads of the package substrate, respectively; and a molding member on the upper surface of the package substrate, the molding member covering the plurality of first semiconductor chips, the second semiconductor chip, and the plurality of vertical wires.

According to example embodiments, a semiconductor package may include a package substrate; a plurality of first semiconductor chips sequentially stacked in a stepwise manner on the package substrate; a second semiconductor chip on an uppermost first semiconductor chip among the plurality of first semiconductor chips, a first surface of the second semiconductor chip including second chip pads and facing the package substrate, the second semiconductor chip having an overhang region protruding from one side of the uppermost first semiconductor chip and an overlapping region overlapping the uppermost first semiconductor chip; conductive bumps on the second chip pads of the second semiconductor chip, the conductive bumps including a plurality of first conductive bumps on the second chip pads in the overhang region of the second semiconductor chip and a plurality of second conductive bumps on the second chip pads in the overlapping region of the second semiconductor chip, the second semiconductor chip being mounted on the uppermost first semiconductor chip using the second conductive bumps on the second chip pads in the overlapping region of the second semiconductor chip; a plurality of bonding wires electrically connecting first chip pads of the plurality of first semiconductor chips to substrate pads of the package substrate; a plurality of vertical wires respectively extending from the plurality of first conductive bumps on the second chip pads in the overhang region to the substrate pads of the package substrate; and a molding member on the package substrate and covering the plurality of first semiconductor chips, the second semiconductor chip, the plurality of bonding wires, and the plurality of vertical wires.

According to example embodiments, a semiconductor package may include a package substrate having an upper surface and a lower surface, the lower surface of the package substrate being opposite the upper surface of the package substrate, the package substrate having a first side portion and a second side portion extending in a direction parallel to a first direction, the first side portion and the second side portion being opposite each other; a plurality of first semiconductor chips sequentially attached on the upper surface of the package substrate, each of the plurality of first semiconductor chips including a first surface including first chip pads facing upward, and the plurality of first semiconductor chips being offset in a second direction, the second direction being perpendicular to the first direction; a second semiconductor chip on an uppermost first semiconductor chip among the plurality of first semiconductor chips, the second semiconductor chip including a first surface including second chip pads facing downward, the second semiconductor chip being offset in the second direction, the second semiconductor chip having an overhang region protruding from one side of the uppermost first semiconductor chip and an overlapping region overlapping the uppermost first semiconductor chip, the second chip pads including a plurality of first bonding pads in the overhang region and a plurality of second bonding pads in the overlapping region; a plurality of first conductive bumps respectively on the plurality of first bonding pads of the second semiconductor chip; a plurality of second conductive bumps respectively on the plurality of second bonding pads of the second semiconductor chip, the plurality of second conductive bumps being between the second semiconductor chip and the uppermost first semiconductor chip; a plurality of vertical wires extending from the plurality of first conductive bumps to substrate pads of the package substrate, respectively; and a molding member on the upper surface of the package substrate, the molding member covering the plurality of first semiconductor chips, the second semiconductor chip, and the plurality of vertical wires.

According to example embodiments, a method of manufacturing a semiconductor package may include providing a package substrate, the package substrate including first substrate pads arranged along a first side portion and second substrate pads arranged along a second side portion, the second side portion being opposite the first side portion; sequentially stacking a plurality of first semiconductor chips in a stepwise manner on the package substrate, an upper surface of the first semiconductor chips including first chip pads; forming a plurality of bonding wires that electrically connect the first chip pads of each of the first semiconductor chips to the first substrate pads of the package substrate; forming a plurality of vertical wires having a length on the second substrate pads of the package substrate respectively; mounting a second semiconductor chip on an uppermost first semiconductor chip among the plurality of first semiconductor chips by bonding conductive bumps on second chip pads of the second semiconductor chip to upper portions of the plurality of vertical wires and the first chip pads of the uppermost first semiconductor chip, respectively; and forming a molding member on the package substrate, the molding member covering the plurality of first semiconductor chips, the second semiconductor chip, the plurality of bonding wires, and the plurality of vertical wires.

According to example embodiments, a semiconductor package may include a plurality of first semiconductor chips and a second semiconductor chip that are sequentially stacked in a stepwise manner on a package substrate. The second semiconductor chip may have an overhang region protruding from one side of an uppermost first semiconductor chip of the plurality of first semiconductor chips and an overlapping region overlapping with the uppermost first semiconductor chip. The second semiconductor chip may be mounted on the uppermost first semiconductor chip using conductive bumps that are formed on second chip pads of the second semiconductor chip. A plurality of vertical wires may extend from the conductive bumps on the second chip pads in the overhang region to second substrate pads of the package substrate. A plurality of bonding wires may electrically connect first chip pads of the first semiconductor chip to first substrate pads of the package substrate.

Since a maximum height of the bonding wire may be smaller than a second height of the second semiconductor chip, the overall thickness of the package may be reduced. In addition, since the vertical wires may be formed directly on the second substrate pads of the package substrate, process steps and equipment for forming a redistribution wiring layer on one surface of a molding member that covers the vertical wires may be unnecessary, so that the manufacturing process may be further simplified. Furthermore, since the conductive bumps may surround at least upper portions of the vertical wires and may make direct contact, the bonding reliability of the vertical wires may be improved.

### BRIEF DESCRIPTION OF THE DRAWINGS

Example embodiments will be more clearly understood from the following detailed description taken in conjunction with the accompanying drawings. FIGS. 1 to 27 represent non-limiting, example embodiments as described herein.

FIG. 1 is a cross-sectional view illustrating a semiconductor package in accordance with example embodiments.

FIG. 2 is a plan view illustrating the semiconductor package of FIG. 1.

FIG. 3 is an enlarged cross-sectional view illustrating portion ‘A’ in FIG. 1.

FIGS. 4 to 14 are views illustrating a method of manufacturing a semiconductor package in accordance with example embodiments.

FIG. 15 is a cross-sectional view illustrating a semiconductor package in accordance with example embodiments.

FIG. 16 is a cross-sectional view illustrating a semiconductor package in accordance with example embodiments.

FIGS. 17 to 20 are cross-sectional views illustrating a method for manufacturing a semiconductor package in accordance with example embodiments.

FIG. 21 is a cross-sectional view illustrating a semiconductor package in accordance with example embodiments.

FIGS. 22 to 25 are cross-sectional views illustrating a method of manufacturing a semiconductor package in accordance with example embodiments.

FIG. 26 is a cross-sectional view illustrating a semiconductor package in accordance with example embodiments.

FIG. 27 is a cross-sectional view illustrating a semiconductor package in accordance with example embodiments.

### DETAILED DESCRIPTION OF EXAMPLE EMBODIMENTS

The notion that elements are “substantially the same” may indicate that the element may be completely the same and may also indicate that the elements may be determined to be the same in consideration of errors or deviations occurring during a process.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

Hereinafter, example embodiments will be explained in detail with reference to the accompanying drawings.

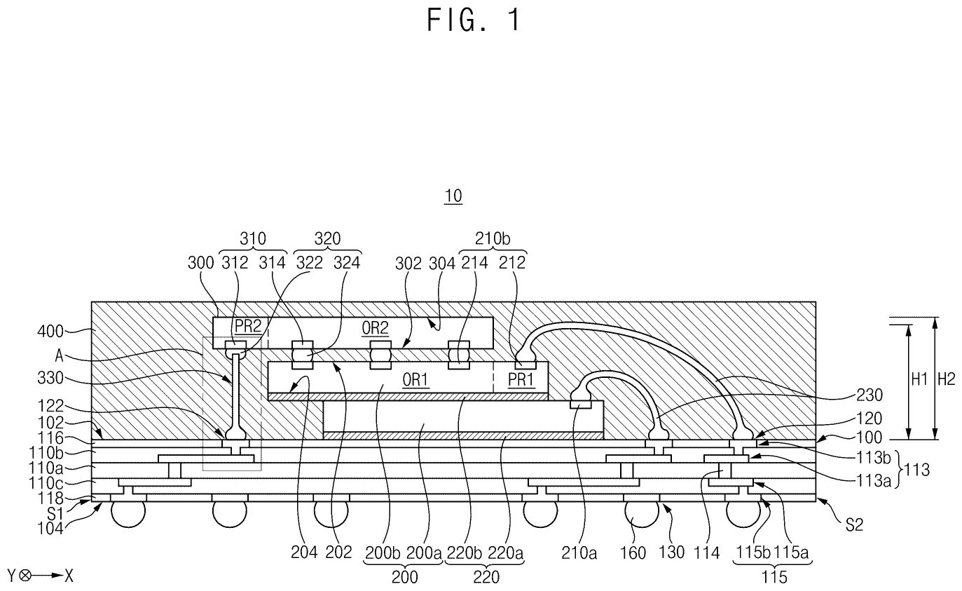

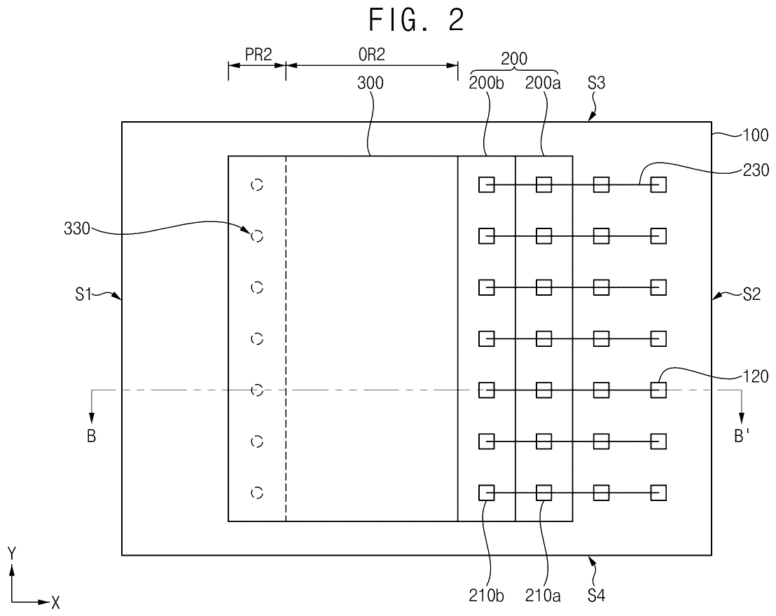

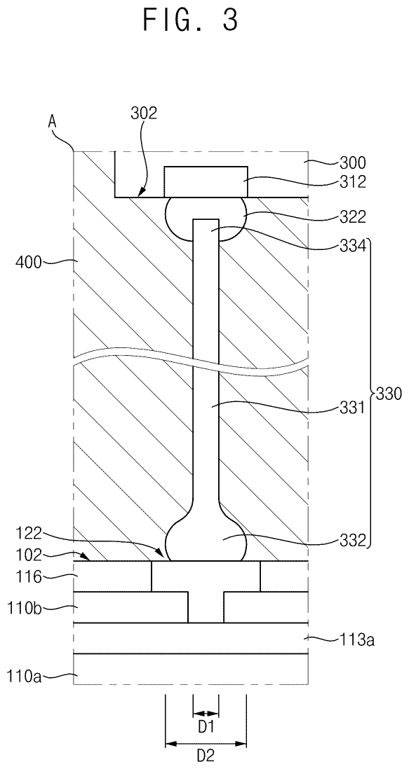

FIG. 1 is a cross-sectional view illustrating a semiconductor package in accordance with example embodiments. FIG. 2 is a plan view illustrating the semiconductor package of FIG. 1. FIG. 3 is an enlarged cross-sectional view illustrating portion ‘A’ in FIG. 1. FIG. 1 includes a cross-section taken along the line B-B′in FIG. 3. FIG. 2 is a plan view illustrating the semiconductor package in FIG. 1, wherein a molding member is omitted.

Referring to FIGS. 1 to 3, a semiconductor package 10 may include a package substrate 100, a plurality of first semiconductor chips 200, a second semiconductor chip 300, vertical wires 330, and a molding member 400. In addition, the semiconductor package 10 may further include bonding wires 230 as conductive connecting members that electrically connect the plurality of first semiconductor chips 200 to the package substrate 110 and external connection members 160 disposed on an outer surface of the package substrate 100.

Additionally, the semiconductor package 10 may be a multi-chip package (MCP) including different types of semiconductor chips. The semiconductor package 10 may be a System In Package (SIP) including a plurality of semiconductor chips stacked or arranged in one package to perform all or most of the functions of an electronic system.

In example embodiments, the package substrate 100 may be a substrate having an upper surface 102 and a lower surface 104 opposite to the upper surface 102. For example, the package substrate 100 may include a printed circuit board PCB, such as a core multilayer substrate. The printed circuit board may be a multilayer circuit board having vias and various circuits therein. Alternatively, the package substrate 100 may include a coreless substrate. The package substrate 100 may include internal wirings as channels for electrical connection with the plurality of first semiconductor chips 200 and the second semiconductor chip 300.

As illustrated in FIG. 2, the package substrate 100 may include a first side portion S1 and a second side portion S2 extending in a direction parallel to the second direction Y direction and facing each other, and a third side portion S3 and a fourth side portion S4 extending in a direction parallel to the first direction (X direction) perpendicular to the second direction and facing each other.

The package substrate 100 may have first substrate pads 120 for electrical connection with the plurality of first semiconductor chips 200 and second substrate pads 122 for electrical connection with the second semiconductor chip 300. The first substrate pads 120 may be arranged to be spaced apart from each other along the second side portion S2 on the upper surface 102 of the package substrate 100. The second substrate pads 122 may be arranged to be spaced apart from each other along the first side portion S1 on the upper surface 102 of the package substrate 100. The first substrate pads 120 and the second substrate pads 122 may be respectively connected to the wirings. The wirings may extend on the upper surface 102 or within the package substrate 100. For example, at least a portion of the wiring may be used as a landing pad for the substrate pad. Although only a few substrate pads are illustrated in the figures, it will be understood that the number, shape, and arrangement of the substrate pads are provided as an example, and the present inventive concept is not limited thereto.

In example embodiments, the package substrate 100 may include a core multilayer substrate. For example, the package substrate 100 may include a core layer 110a, an upper insulating layer 110b on an upper surface of the core layer 110a, and a lower insulating layer 110c on a lower surface of the core layer 110a. The package substrate 100 may further include a plurality of through vias 114 penetrating the core layer 110a, a first upper circuit layer 113a on the upper surface of the core layer 110a, a second upper circuit layer 113b provided on the upper insulating layer 110b, a first lower circuit layer 115a on the lower surface of the core layer 110a, and a second lower circuit layer 115b provided on the lower insulating layer 110c. Protective layers 116, 118 such as solder resist layers may be formed on outermost surfaces of the circuit layers. An upper protective layer 116 may cover the entire upper surface of the insulating layers except for the first substrate pads 120. A lower protective layer 118 may cover the entire lower surface of the insulating layers except for the lower substrate pads 130.

Each of the circuit layers may include a wiring pattern. Each of the wiring patterns may include a pad, a trace, a via, etc. An upper surface of the upper protective layer 116 may be provided as the upper surface 102 of the package substrate 100, and a lower surface of the lower protective layer 118 may be provided as the lower surface 104 of the package substrate 100. At least portions of pads of the second upper circuit layer 113b may be provided as the first and second substrate pads 120, 122 and at least a portion of a pad of the second lower circuit layer 115b may be provided as the lower substrate pad 130.

In example embodiments, the plurality of first semiconductor chips 200 may be sequentially stacked on the package substrate 100.

For example, two first semiconductor chips 200a, 200b may be sequentially attached on the upper surface 102 of the package substrate 100 using adhesive films 220a, 220b. The first semiconductor chips 200a, 200b may be sequentially attached on the package substrate 100 using the adhesive films such as a die attach film (DAF) by a die attach process. For example, a thickness of the semiconductor chip may be within a range of 25 μm to 200 μm. A thickness of the adhesive film may be within a range of 2 μm to 60 μm.

The first semiconductor chip may include a memory chip including a memory circuit. For example, the first semiconductor chip may include volatile memory devices such as SRAM devices, DRAM devices, etc., and non-volatile memory devices such as flash memory devices, PRAM devices, MRAM devices, RRAM devices, etc. In this embodiment, the second semiconductor chip may include DRAM devices.

The first semiconductor chips 200a, 200b may be arranged such that a second surface 204, e.g., an inactive surface, opposite to a first surface 202 on which first chip pads 210a, 210b are formed, face the package substrate 100. Each of the first semiconductor chips 200a, 200b may have a rectangular shape having four sides when viewed in plan view. The first and second side surfaces of each of the first semiconductor chips may be arranged to be parallel to the first direction (X direction), and third and fourth side surfaces of each of the first semiconductor chips may be arranged to be parallel to the second direction (Y direction) perpendicular to the first direction.

In example embodiments, the first semiconductor chips 200a, 200b may be stacked in a cascade structure on the package substrate 100. The uppermost first semiconductor chip 200b may be offset aligned in a first horizontal direction (−X direction) on the lowermost first semiconductor chip 200a. The uppermost first semiconductor chip 200b may be offset aligned in the first horizontal direction such that the first chip pads 210a of the lowermost first semiconductor chip 200a are exposed.

The lowermost first semiconductor chip 200a may include an overhang portion protruding from one side (second side surface) of the uppermost first semiconductor chip 200b. When viewed in plan view, the first chip pads 210a of the lowermost first semiconductor chip 200a may be arranged in an edge region along one side (second side surface) of the lowermost first semiconductor chip 200a on an upper surface of the overhang portion protruding from one side (second side surface) of the uppermost first semiconductor chip 200b. The first chip pads 210a may be arranged to be spaced apart from each other in the second direction (Y direction) on the first surface 202 of the first semiconductor chip 200a.

In example embodiments, the uppermost first semiconductor chip 200b may include a first region, e.g., an overhang region PR1 protruding from one side of the second semiconductor chip disposed on the uppermost first semiconductor chip 200b, and a second region, e.g., an overlapping region OR1 overlapping the second semiconductor chip. The first chip pads 210b may include a plurality of first bonding pads 212 and a plurality of second bonding pads 214.

The plurality of first bonding pads 212 may be arranged in an edge region along one side (second side surface) of the uppermost first semiconductor chip 200b on the upper surface, e.g., the front surface 202, of the overhang region PR1 of the uppermost first semiconductor chip 200b. The plurality of first bonding pads 212 may be arranged to be spaced apart from each other in the second direction (Y direction) on the first surface 202 of the first semiconductor chip 200b. The plurality of second bonding pads 214 may be arranged in an array form on the upper surface, e.g., the front surface 202 of the overlapping region OR1 of the uppermost first semiconductor chip 200b.

It will be understood that the number, size, arrangement, etc. of the first semiconductor chips are provided as an example, and the present inventive concept is not limited thereto. Also, although only a few chip pads are illustrated in the figures, it will be understood that the structure, shape, and arrangement of the first chip pads are provided as an example, and the present inventive concept is not limited thereto.

For example, the plurality of first semiconductor chips 200 may be offset-aligned in a diagonal direction with respect to the first semiconductor chip disposed below. The diagonal direction may include the first horizontal direction (−X direction) and a second horizontal direction (Y direction) perpendicular to the first horizontal direction.

The first semiconductor chips 200 may be electrically connected to the package substrate 100 by bonding wires 230 as conductive connecting members. In particular, the first chip pads 210a of the lowermost first semiconductor chip 200a and the plurality of first bonding pads 212 of the uppermost first semiconductor chip 200b may be electrically connected to the first substrate pads 120 on the upper surface 102 of the package substrate 100 by the bonding wires 230.

In example embodiments, vertical wires 330 as vertical conductive structures may extend vertically on the second substrate pads 122 of the package substrate 100 by a desired and/or alternatively predetermined length, respectively. The vertical wires 330 may be spaced apart from each other along the first side portion S1 on the second substrate pads 122 of the package substrate 100. The length of the vertical wire 330 may be greater than or equal to a height of the uppermost first semiconductor chip 200b from the package substrate 100.

The vertical wire 330 may include a wire body 331 extending in a vertical direction, a first bonding end portion 332 provided at a first end portion of the wire body 331 and bonded to the second substrate pad 122, and a second bonding end portion 334 provided at a second end portion of the wire body 331. The wire body 331 may have a first diameter DI, and the first bonding end portion 332 may have a second diameter D2 greater than the first diameter. For example, the first diameter may be within a range of 10 μm to 50 μm. The vertical wire may include copper (Cu), gold (Au), or aluminum (Al).

In example embodiments, the second semiconductor chip 300 may be mounted on the uppermost first semiconductor chip 200b via conductive bumps 320. The conductive bumps 320 may include solder bumps.

The second semiconductor chip 300 may be the same type of chip as the first semiconductor chip 200 or may be a different type of chip from the first semiconductor chip 200. The second semiconductor chip may include a memory chip including a memory circuit. For example, the second semiconductor chip may include volatile memory devices such as SRAM devices, DRAM devices, etc., and non-volatile memory devices such as flash memory devices, PRAM devices, MRAM devices, RRAM devices, etc.

In example embodiments, the second semiconductor chip 300 may be stacked in a stepwise manner on the uppermost first semiconductor chip 200b. The second semiconductor chip 300 may be offset aligned in the first horizontal direction (−X direction) on the uppermost first semiconductor chip 200b. The second semiconductor chip 300 may include a third region, e.g., an overhang region PR2, protruding from one side (first side surface) of the uppermost first semiconductor chip 200b disposed below, and a fourth region, e.g., an overlapping region OR2, overlapping with the uppermost first semiconductor chip 200b.

The second semiconductor chip 300 may be arranged such that a first surface 302 on which second chip pads 310 are formed faces the package substrate 100. The first surface 302 of the second semiconductor chip 300 and the first surface 302 of the uppermost first semiconductor chip 200b may face each other. The second chip pads 310 may include a plurality of third bonding pads 312 and a plurality of fourth bonding pads 314.

The plurality of third bonding pads 312 may be arranged in an edge region along one side surface of the second semiconductor chip 300 on a lower surface, e.g., the front surface 302 of the overhang region PR2 of the second semiconductor chip 300. The plurality of third bonding pads 312 may be arranged to be spaced apart from each other in the second direction (Y direction) on the first surface 302 of the second semiconductor chip 300 so as to respectively correspond to the second bonding end portions 334 of the vertical wires 330. The plurality of third bonding pads 312 may be arranged in a zigzag shape in the second direction (Y direction) along one side of the second semiconductor chip 300.

The plurality of fourth bonding pads 314 may be arranged in an array form on the lower surface, e.g., the front surface 302 of the overlapping region OR2 of the second semiconductor chip 300. The plurality of fourth bonding pads 314 may be arranged to be spaced apart from each other on the first surface 302 of the second semiconductor chip 300 so as to correspond to the plurality of second bonding pads 214 of the uppermost first semiconductor chip 200b, respectively.

The second semiconductor chip 300 may be mounted on the uppermost first semiconductor chip 200b in a flip chip manner. The conductive bumps 320 may include a plurality of first conductive bumps 322 and a plurality of second conductive bumps 324. The first conductive bumps 322 may be solder bumps for bonding with the vertical wires 330, and the second conductive bumps 324 may be solder bumps for bonding with the bonding pads of the uppermost first semiconductor chip 200b.

The first conductive bumps 322 may be provided on the plurality of third bonding pads 312 of the second semiconductor chip 300, respectively. The first conductive bumps 322 may surround upper portions of the vertical wires 330, that is, at least portions of the second bonding end portions 334, respectively. The first conductive bumps 322 may be in contact with the second bonding end portions 334 of the vertical wires 330, respectively. The vertical wire 330 may extend from the first conductive bump 322 to the second substrate pad 122 of the package substrate 100. Accordingly, the vertical wire 330 may be electrically connected to the third bonding pad 312 by the first conductive bump 322, and the second semiconductor chip 300 may be electrically connected to the package substrate 100 by the vertical wires 330.

The second conductive bumps 324 may be provided on the plurality of fourth bonding pads 314 of the second semiconductor chip 300, respectively. The second conductive bumps 324 may be interposed between the fourth bonding pads 314 of the second semiconductor chip 300 and the second bonding pads 214 of the uppermost first semiconductor chip 200b, respectively. The second conductive bumps 324 may be used as bonding dummy bumps for bonding the second semiconductor chip 300 to the uppermost first semiconductor chip 200b. The plurality of second bonding pads 214 of the uppermost first semiconductor chip 200b and the plurality of fourth bonding pads 314 of the second semiconductor chip 300 may be dummy pads to which no electrical signals are transmitted. Alternatively, the plurality of second bonding pads 214 and the plurality of fourth bonding pads 314 may be signal transmission pads through which electrical signals are transmitted, and in this case, the uppermost first semiconductor chip 200b and the second semiconductor chip 300 may be electrically connected by the second conductive bump 324.

The bonding wire 230 may have a first height H1 as a maximum height from the upper surface 102 of the package substrate 100, and the second semiconductor chip 300 may have a second height H2 greater than the first height H1 from the upper surface 102 of the package substrate 100.

In example embodiments, the molding member 400 may cover the plurality of first semiconductor chips 200, the second semiconductor chip 300, the bonding wires 230, and the conductive wires 330 on the upper surface 102 of the package substrate 100.

The molding member 400 may include a thermosetting resin, for example, an epoxy mold compound EMC. A gap may be provided between the uppermost first semiconductor chip 200b and the second semiconductor chip 300 by the second conductive bump 324. A portion of the molding member 400 may be provided to surround the plurality of second conductive bumps 324 between the uppermost first semiconductor chip 200b and the second semiconductor chip 300.

In example embodiments, the external connection members 160 may be disposed on the lower surface 104 of the package substrate 100. For example, the external connection members may include solder balls, solder bumps, etc. The semiconductor package 10 may be mounted on a lower package, an interposer, a module substrate, etc., via the external connection members 160 to form a memory device.

As mentioned above, the semiconductor package 10 may include the plurality of first semiconductor chips 200 and the second semiconductor chip 300 that are sequentially stacked in a stepwise manner on the package substrate 100. The first surface 302 on which the second chip pads 310 of the second semiconductor chip 300 are formed may be arranged to face the first surface 202 on which the first chip pads 210b of the uppermost first semiconductor chip 200b are formed. The second semiconductor chip 300 may be mounted on the uppermost first semiconductor chip 200b via the conductive bumps 320. The second semiconductor chip 300 may have the overhang region PR2 protruding from one side of the uppermost first semiconductor chip 200b and the overlapping region OR2 overlapping with the uppermost first semiconductor chip 200b, and the conductive bumps 320 may include the plurality of first conductive bumps 322 formed respectively on the plurality of third bonding pads 312 provided in the overhang region PR2 and the plurality of second conductive bumps 324 formed respectively on the plurality of fourth bonding pads 314 provided in the overlapping region OR2. The plurality of vertical wires 330 may extend from the plurality of first conductive bumps 322 to the second substrate pads 122 of the package substrate 100. The plurality of bonding wires 230 may electrically connect the first chip pads 210a, 210b of the first semiconductor chip 200 to the first substrate pads 120 of the package substrate 100.

The second semiconductor chip 300 may be electrically connected to the package substrate 100 by the vertical wires 330. Since the maximum height H1 of the bonding wire 230 is smaller than the second height H2 of the second semiconductor chip 300, the overall thickness of the package may be reduced. In addition, since the vertical wires 300 are formed directly on the second substrate pads 122 of the package substrate 100, process steps and equipment for forming a redistribution wiring layer on one surface of the molding member that covers the vertical wires are unnecessary, so that the manufacturing process may be further simplified. Furthermore, since the plurality of first conductive bumps 322 surround the at least portions of the upper portions of the vertical wires 330 and make direct contact, the bonding reliability of the vertical wires 330 may be improved.

Hereinafter, a method of manufacturing the semiconductor package in FIG. 1 will be explained.

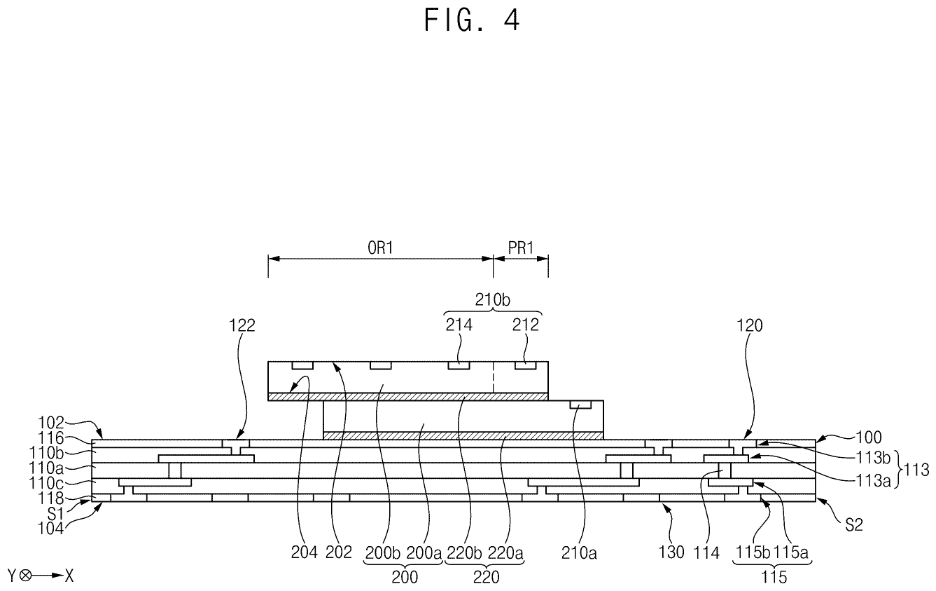

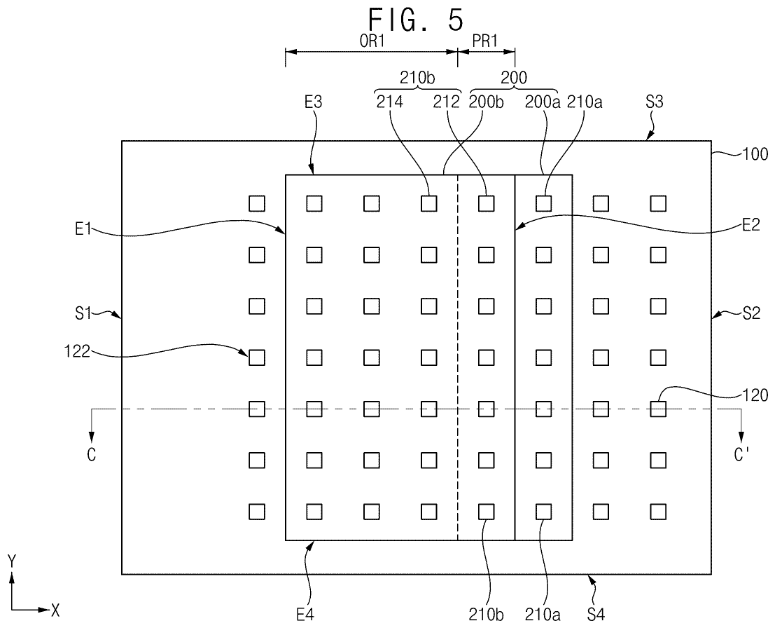

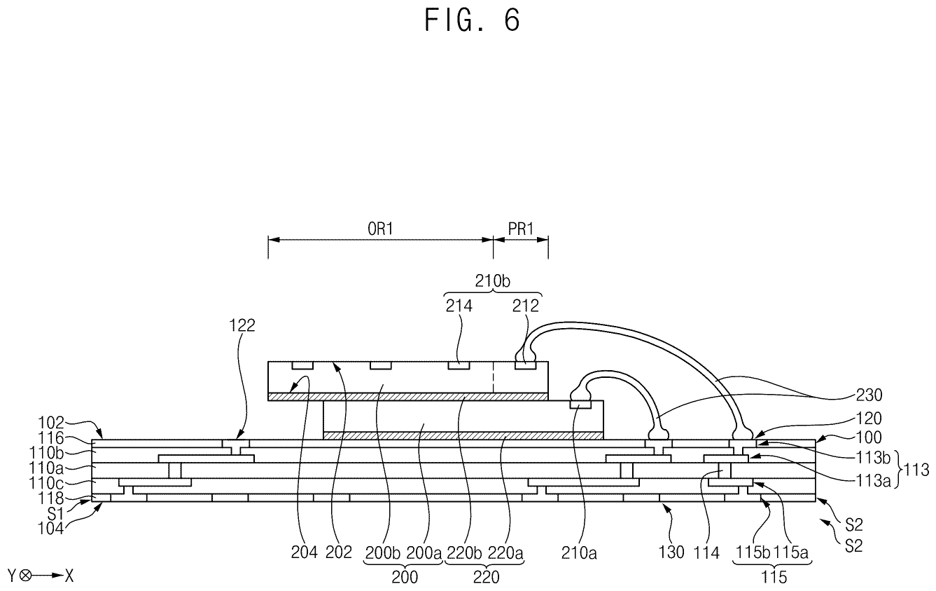

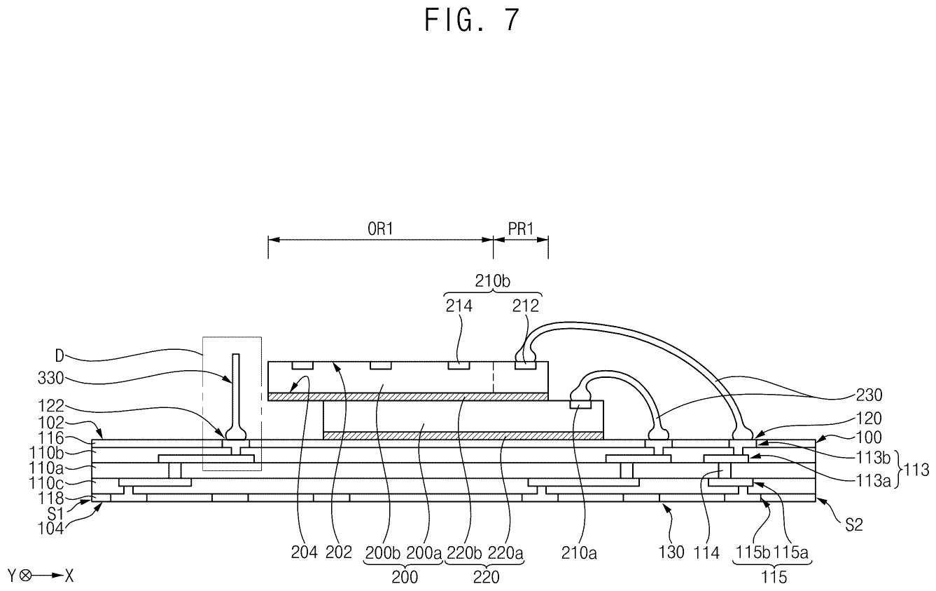

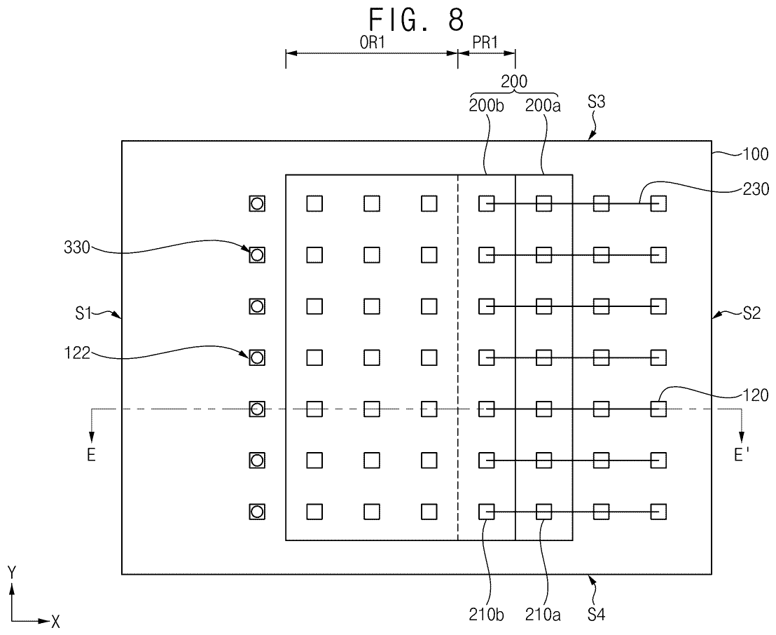

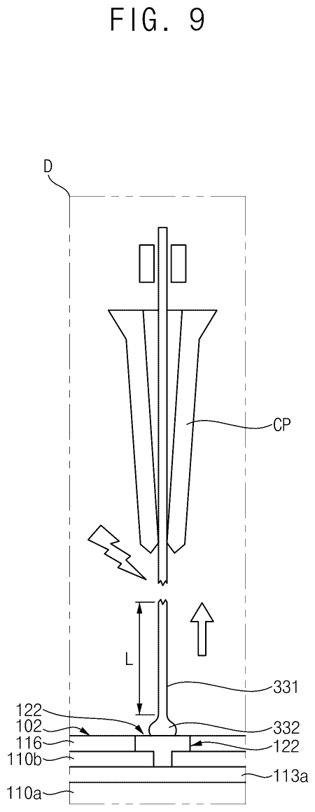

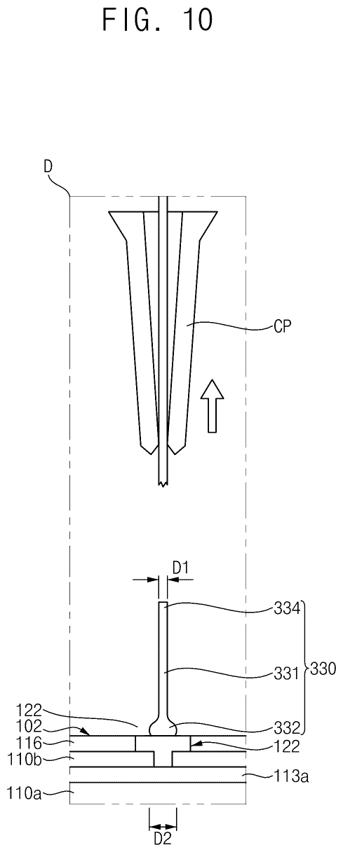

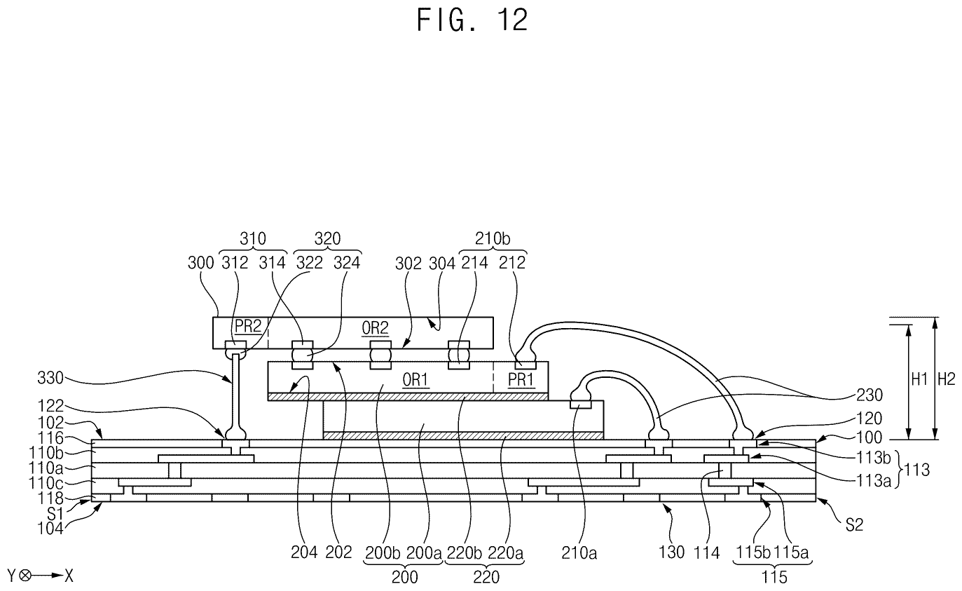

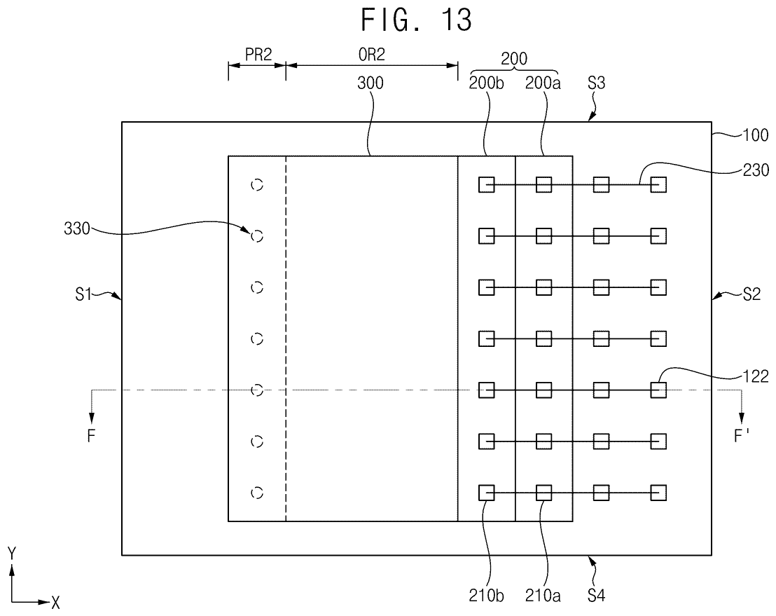

FIGS. 4 to 14 are views illustrating a method of manufacturing a semiconductor package in accordance with example embodiments. FIGS. 4, 6, 7, 11, 12 and 149 are cross-sectional views illustrating a method of manufacturing a semiconductor package in accordance with example embodiments. FIG. 5 is a plan view of FIG. 4. FIG. 8 is a plan view of FIG. 7. FIGS. 9 and 10 are enlarged cross-sectional view illustrating a process of forming a vertical wire in portion ‘D’ in FIG. 7. FIG. 13 is a plan view of FIG. 12. FIG. 4 is a cross-sectional view taken along the line C-C′ in FIG. 5. FIG. 6 is a cross-sectional view taken along the line E-E′ in FIG. 8. FIG. 12 is a cross-sectional view taken along the line F-F′ in FIG. 13.

Referring to FIGS. 4 and 5, a plurality of first semiconductor chips 200 may be sequentially stacked on a package substrate 100.

In example embodiments, the package substrate 100 may be a multilayer circuit substrate having an upper surface 102 and a lower surface 104. For example, the package substrate 100 may be a printed circuit board PCB including wirings provided in each of a plurality of layers and vias for connecting them. The package substrate 100 may be a strip substrate for manufacturing a semiconductor strip such as PCB.

As illustrated in FIG. 5, the package substrate 100 may include a first side portion S1 and a second side portion S2 that extend in a direction parallel to a second direction (Y direction) and face each other, and a third side portion S3 and a fourth side portion S4 that extend in a direction parallel to a first direction (X direction) that is perpendicular to the second direction and face each other.

The package substrate 100 may have first substrate pads 120 for electrical connection with a plurality of first semiconductor chips 200 and second substrate pads 122 for electrical connection with a second semiconductor chip to be described later. The first substrate pads 120 may be arranged to be spaced apart from each other along the second side portion S2 on the upper surface 102 of the package substrate 100. The second substrate pads 122 may be arranged to be spaced apart from each other along the first side portion S1 on the upper surface 102 of the package substrate 100. The first substrate pads 120 and the second substrate pads 120 may be respectively connected to the wirings. The wirings may extend on the upper surface 102 or within the package substrate 100. For example, at least a portion of the wiring may be used as a landing pad for the substrate pad. Although only a few substrate pads are illustrated in the figures, it will be understood that the number, shape, and arrangement of the substrate pads are provided as an example, and the present inventive concept is not limited thereto.

In example embodiments, the package substrate 100 may include a core multilayer substrate. For example, the package substrate 100 may include a core layer 110a, an upper insulating layer 110b on an upper surface of the core layer 110a, and a lower insulating layer 110c on a lower surface of the core layer 110a. The package substrate 100 may further include a plurality of through vias 114 penetrating the core layer 110a, a first upper circuit layer 113a on the upper surface of the core layer 110a, a second upper circuit layer 113b provided on the upper insulating layer 110b, a first lower circuit layer 115a on the lower surface of the core layer 110a, and a second lower circuit layer 115b provided on the lower insulating layer 110c. Protective layers 116, 118 such as solder resist layers may be formed on outermost surfaces of the circuit layers. An upper protective layer 116 may cover the entire upper surface of the insulating layers except for the first and second substrate pads 120, 122. A lower protective layer 118 may cover the entire lower surface of the insulating layers except for lower substrate pads 130.

Each of the circuit layers may include a wiring pattern. Each of the wiring patterns may include a pad, a trace, a via, etc. An upper surface of the upper protective layer 116 may be provided as the upper surface 102 of the package substrate 100, and a lower surface of the lower protective layer 118 may be provided as the lower surface 104 of the package substrate 100. At least portions of pads of the second upper circuit layer 113b may be provided as the first and second substrate pads 120, 122 and at least a portion of a pad of the second lower circuit layer 115b may be provided as the lower substrate pad 130.

In example embodiments, two first semiconductor chips 200a, 200b may be sequentially stacked on the package substrate 100. Individual semiconductor chips diced from a wafer by a dicing process may be provided as the first semiconductor chips.

The first semiconductor chips 200a, 200b may be sequentially attached onto the upper surface 102 of the package substrate 100 using adhesive films 220a, 220b. The first semiconductor chips 200a, 200b may be sequentially attached to the package substrate 100 using the adhesive films such as a die attach film (DAF) by a die attach process. For example, a thickness of the first semiconductor chip may be within a range of 25 μm to 200 μm. A thickness of the adhesive film may be within the range of 2 μm to 60 μm.

The first semiconductor chips 200a, 200b may be arranged such that a second surface 204, e.g., an inactive surface opposite to a first surface 202 on which first chip pads 210a, 210b are formed, faces the package substrate 100. Each of the first semiconductor chips 200a, 200b may have a quadrangular shape having four sides when viewed in plan view. A first side surface E1 and a second side surface E2 of each of the first semiconductor chips may be arranged to be parallel to the first direction (X direction), and a third side surface E3 and a fourth side surface E4 of each of the first semiconductor chips may be arranged to be parallel to the second direction (Y direction) perpendicular to the first direction.

In example embodiments, the first semiconductor chips 200a, 200b may be stacked in a cascade structure on the package substrate 100. The uppermost first semiconductor chip 200b may be aligned with an offset in a first horizontal direction (−X direction) on the lowermost first semiconductor chip 200a. The uppermost second semiconductor chip 200b may be offset aligned in the first horizontal direction such that the first chip pads 210a of the lowermost first semiconductor chip 200a are exposed from the uppermost second semiconductor chip 200b.

The first semiconductor chip may include a memory chip including a memory circuit. For example, the first semiconductor chip may include volatile memory devices such as SRAM devices, DRAM devices, etc., and non-volatile memory devices such as flash memory devices, PRAM devices, MRAM devices, RRAM devices, etc. In this embodiment, the second semiconductor chip may include DRAM devices.

In example embodiments, the lowermost first semiconductor chip 200a may include an overhang portion protruding from one side (second side surface) of the uppermost first semiconductor chips 200b. When viewed in plan view, the first chip pads 210a of the lowermost first semiconductor chip 200a may be arranged in an edge region along one side (second side surface) of the lowermost first semiconductor chip 200a on an upper surface of the overhang portion protruding from one side (second side surface) of the uppermost first semiconductor chip 200b. The first chip pads 210a may be arranged spaced apart from each other in the second direction (Y direction) on the first surface 202 of the first semiconductor chip 200a.

In example embodiments, the uppermost first semiconductor chip 200b may include a first region, e.g., an overhang region PR1 protruding from one side of a second semiconductor chip to be disposed on the uppermost first semiconductor chip, and a second region, e.g., an overlapping region OR1 overlapping the second semiconductor chip. The first chip pads 210b may include a plurality of first bonding pads 212 and a plurality of second bonding pads 214.

The plurality of first bonding pads 212 may be arranged in an edge region along one side (second side surface) of the uppermost first semiconductor chip 200b on the upper surface, e.g., the front surface 202 of the overhang region PR1 of the uppermost first semiconductor chip 200b. The plurality of first bonding pads 212 may be arranged spaced apart from each other in the second direction (Y direction) on the first surface 202 of the first semiconductor chip 200b. The plurality of second bonding pads 214 may be arranged in an array form on the upper surface, e.g., the front surface 202 of the overlapping region ORI of the uppermost first semiconductor chip 200b.

It will be understood that the number, size, arrangement, etc. of the first semiconductor chips are provided as an example, and the present inventive concept is not limited thereto. Also, although only a few chip pads are illustrated in the figures, it will be understood that the structure, shape, and arrangement of the first chip pads are provided as an example, and the present inventive concept is not limited thereto.

Referring to FIG. 6, the plurality of first semiconductor chips 200 may be electrically connected to the package substrate 100 by conductive connecting members 230.

In example embodiments, a wire bonding process may be performed to electrically connect the first chip pads 210a of the lowermost first semiconductor chip 200a and the plurality of first bonding pads 212 of the uppermost first semiconductor chip 200b to the first substrate pads 120 on the upper surface 102 of the package substrate 100 by using the bonding wires 230.

Referring to FIGS. 7 to 10, a plurality of vertical wires 330 as vertical conductive structures may be formed on the second substrate pads 122 of the package substrate 100. The vertical wires 330 may be bonding wires formed by a wire bonding process. The vertical wires 330 may be spaced apart along the first side portion S1 on the second substrate pads 122 of the package substrate 100.

As illustrated in FIGS. 9 and 10, after one end portion of a wire drawn from a capillary CP of a wire bonding apparatus is bonded to the second substrate pad 122 of the package substrate 100, the capillary CP may move in an upward vertical direction to withdraw the wire. Then, when the wire is extended by a desired and/or alternatively predetermined length L, a portion of the wire may be cut to form the conductive wire 330. The length L of the vertical wire 330 may be greater than or equal to a height of the uppermost first semiconductor chip 200b from the package substrate 100.

Accordingly, the conductive wire 330 may include a wire body 331 extending in the vertical direction, a first bonding end portion 332 provided at a first end portion of the wire body 331 and bonded to the second substrate pad 122, and a second bonding end portion 334 provided at a second end portion opposite to the first end portion of the wire body 331. The wire body 331 may have a first diameter D1, and the first bonding end portion 332 may have a second diameter D2 greater than the first diameter. For example, the first diameter may be within a range of 10 μm to 50 μm. The vertical wire may include copper (Cu), gold (Au), or aluminum (Al).

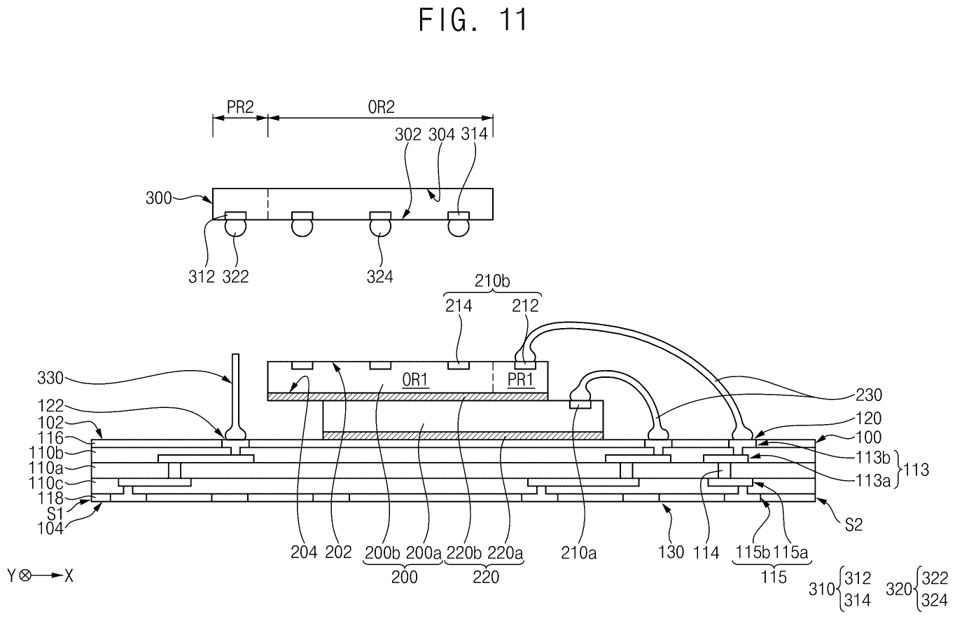

Referring to FIGS. 11 to 13, a second semiconductor chip 300 may be disposed the uppermost first semiconductor chip 200b via conductive bumps 320.

In example embodiments, an individual semiconductor chip diced from a wafer by a dicing process may be provided as the second semiconductor chip. The second semiconductor chip 300 may be the same type as the first semiconductor chip 200 or a different type from the first semiconductor chip 200.

The second semiconductor chip may include a memory chip including a memory circuit. For example, the second semiconductor chip may include volatile memory devices such as SRAM devices, DRAM devices, etc., and non-volatile memory devices such as flash memory devices, PRAM devices, MRAM devices, RRAM devices, etc. In this embodiment, the second semiconductor chip may include DRAM devices.

In example embodiments, the second semiconductor chip 300 may be stacked in a stepwise manner on the uppermost first semiconductor chip 200b. The second semiconductor chip 300 may be offset aligned in the first horizontal direction (−X direction) on the uppermost first semiconductor chip 200b. The second semiconductor chip 300 may include a third region, e.g., an overhang region PR2, protruding from one side (first side surface) of the uppermost first semiconductor chip 200b disposed below, and a fourth region, e.g., an overlapping region OR2, overlapping with the uppermost first semiconductor chip 200b.

The second semiconductor chip 300 may be arranged such that a first surface 302 on which second chip pads 310 are formed faces the package substrate 100. The first surface 302 of the second semiconductor chip 300 and the first surface 202 of the uppermost first semiconductor chip 200b may face each other. The second chip pads 310 may include a plurality of third bonding pads 312 and a plurality of fourth bonding pads 314.

The plurality of third bonding pads 312 may be arranged in an edge region along one side surface of the second semiconductor chip 300 on a lower surface, e.g., the front surface 302 of the overhang region PR2 of the second semiconductor chip 300. The plurality of third bonding pads 312 may be arranged spaced apart from each other in the second direction (Y direction) on the first surface 302 of the second semiconductor chip 300 so as to correspond to the second bonding end portions 334 of the vertical wires 330, respectively.

The plurality of fourth bonding pads 314 may be arranged in an array form on the lower surface, e.g., the front surface 302 of the overlapping region OR2 of the second semiconductor chip 300. The plurality of fourth bonding pads 314 may be arranged spaced apart from each other on the first surface 302 of the second semiconductor chip 300 so as to correspond to the plurality of second bonding pads 214 of the uppermost first semiconductor chip 200b, respectively.

As illustrated in FIGS. 11 and 12, the second semiconductor chip 300 may be mounted on the uppermost first semiconductor chip 200b in a flip chip manner. After the conductive bumps 320 are respectively formed on the second chip pads 310 of the second semiconductor chip 300, flux may be applied on the conductive bumps 320. Then, the second semiconductor chip 300 may be placed on the uppermost first semiconductor chip 200b and the plurality of vertical wires 330 with the conductive bumps 320 interposed therebetween, and then a soldering process may be performed to bond the conductive bumps 320 to the plurality of second bonding pads 214 of the uppermost first semiconductor chip 200b and the second bonding end portions 334 of the vertical wires 330. During the soldering process, an oxide layer on surfaces of the conductive bumps 320 may be removed by the flux, so that the conductive bumps 320 may be bonded to the plurality of second bonding pads 214 of the uppermost first semiconductor chip 200b and the second bonding end portions 334 of the vertical wires 330, respectively.

The conductive bumps 320 may include a plurality of first conductive bumps 322 and a plurality of second conductive bumps 324.

The first conductive bumps 322 may be formed on the plurality of third bonding pads 312 of the second semiconductor chip 300, respectively. The first conductive bumps 322 may be formed to surround upper portions of the vertical wires 330, that is, at least portions of the second bonding end portions 334. The first conductive bumps 322 may contact the second bonding end portions 334 of the vertical wires 330 respectively. Accordingly, the vertical wires 330 may be electrically connected to the third bonding pads 312 by the first conductive bumps 322. Since the first conductive bumps 322 surround and directly contact the at least portions of the upper portions of the vertical wires 330, the bonding reliability of the vertical wires 330 may be improved.

The second conductive bumps 324 may be formed on the plurality of fourth bonding pads 314 of the second semiconductor chip 300, respectively. The second conductive bumps 324 may be interposed between the fourth bonding pads 314 of the second semiconductor chip 300 and the second bonding pads 214 of the uppermost first semiconductor chip 200b, respectively. The second conductive bumps 324 may be used as dummy bumps for bonding the second semiconductor chip 300 to the uppermost first semiconductor chip 200b. The plurality of second bonding pads 214 of the uppermost first semiconductor chip 200b and the plurality of fourth bonding pads 314 of the second semiconductor chip 300 may be dummy pads to which no electrical signals are transmitted.

Alternatively, the plurality of second bonding pads 214 and the plurality of fourth bonding pads 314 may be signal transmission pads through which electrical signals are transmitted, and in this case, the uppermost first semiconductor chip 200b and the second semiconductor chip 300 may be electrically connected by the second conductive bump 324.

The bonding wire 230 may have a first height H1 as a maximum height from the upper surface 102 of the package substrate 100, and the second semiconductor chip 300 may have a second height H2 greater than the first height H1 from the upper surface 102 of the package substrate 100.

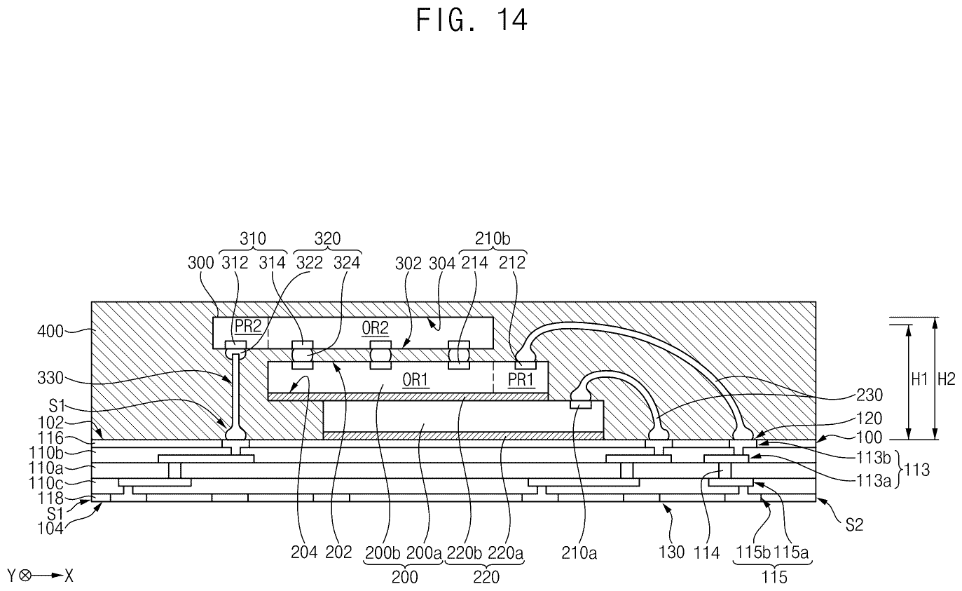

Referring to FIG. 14, a molding member 400 may be formed on the upper surface 102 of the package substrate 100 to cover the plurality of first semiconductor chips 200, the second semiconductor chip 300, the bonding wires 230, and the conductive wires 330.

In example embodiments, the molding member 400 may be formed on the package substrate 100 by a transfer molding apparatus. A molding material may be formed on the upper surface 102 of the package substrate 100 to cover the plurality of first semiconductor chips 200 and the second semiconductor chip 300, and an upper portion of the molding material may be partially removed to have a desired height. The molding member 400 may be formed to completely cover the second semiconductor chip 300. The molding member 400 may include a thermosetting resin, for example, an epoxy mold compound EMC.

A gap may be formed between the uppermost first semiconductor chip 200b and the second semiconductor chip 300 by the second conductive bumps 324. At least a portion of the molding member 400 may be formed to surround the plurality of second conductive bumps 324 between the uppermost first semiconductor chip 200b and the second semiconductor chip 300.

Then, external connection members (160, see FIG. 1 may be formed on the lower substrate pads 130 on the lower surface 104 of the package substrate 100 to complete the semiconductor package 10 of FIG. 1.

For example, the external connection members may include solder balls, solder bumps, etc. The external connection members may be formed on the lower substrate pads 130 of the lower surface 104 of the package substrate 100 by a solder ball attach process.

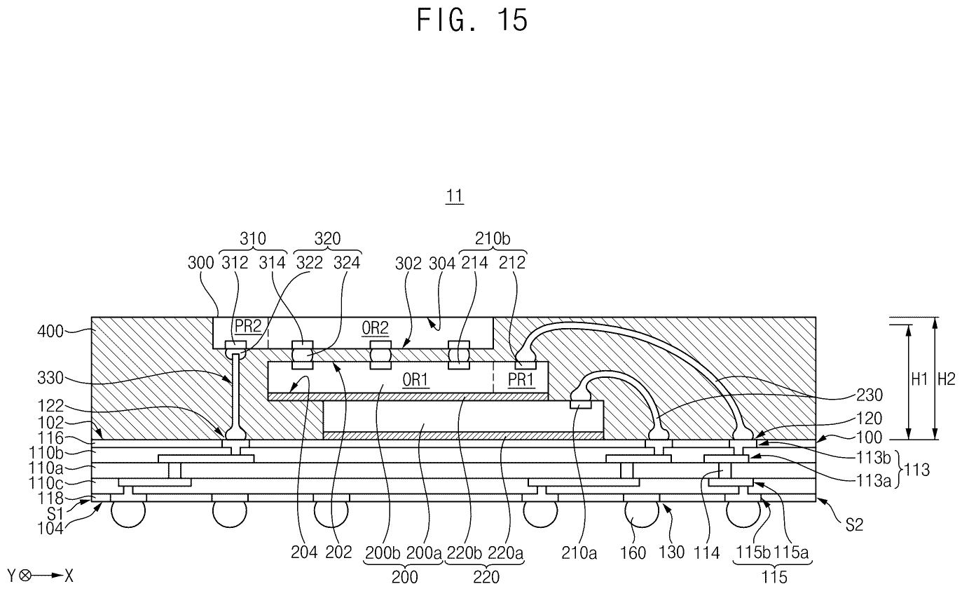

FIG. 15 is a cross-sectional view illustrating a semiconductor package in accordance with example embodiments. The semiconductor package may be substantially the same as or similar to the semiconductor package described with reference to FIGS. 1 to 3 except for a configuration of a molding member. Thus, same reference numerals will be used to refer to the same or like elements and any further repetitive explanation concerning the above elements will be omitted.

Referring to FIG. 15, a molding member 400 of a semiconductor package 11 may cover a plurality of first semiconductor chips 200, a second semiconductor chip 300, bonding wires 230, and conductive wires 330 on an upper surface 102 of a package substrate 100.

In example embodiments, the molding member 400 may expose at least a portion of an upper surface, e.g., a second surface 304 of the second semiconductor chip 300. Since the at least a portion of the second surface 304 of the second semiconductor chip 300 is exposed, heat dissipation characteristics from the second semiconductor chip 300 to the outside may be improved.

In addition, since the second surface 304 of the second semiconductor chip 300 and an upper surface of the molding member 400 are positioned on the same plane, the overall thickness of the package may be reduced.

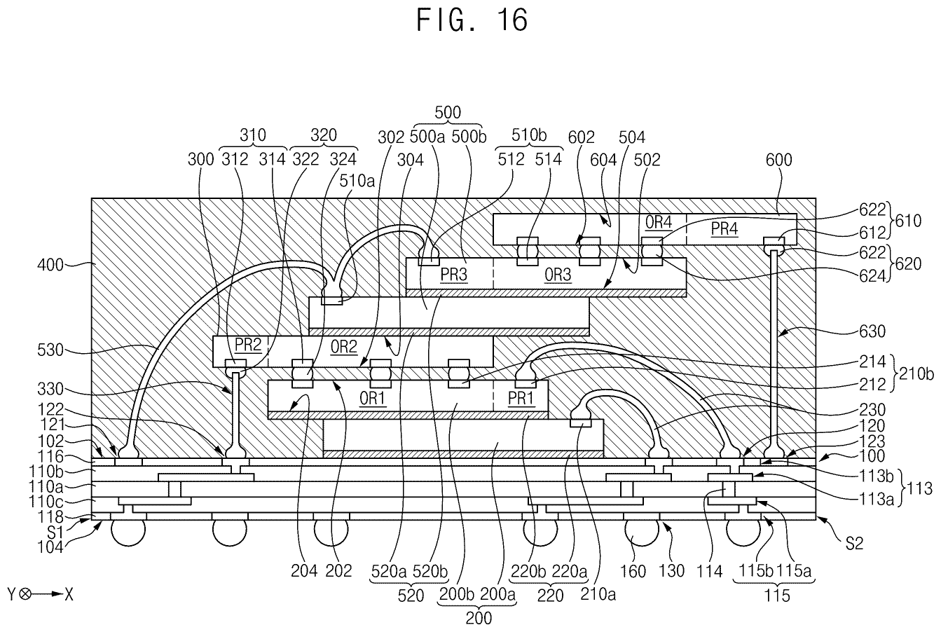

FIG. 16 is a cross-sectional view illustrating a semiconductor package in accordance with example embodiments. The semiconductor package may be substantially the same as or similar to the semiconductor package described with reference to FIGS. 1 to 3 except for additional configurations of a plurality of third semiconductor chips, a fourth semiconductor chip and second vertical wires. Thus, same reference numerals will be used to refer to the same or like elements and any further repetitive explanation concerning the above elements will be omitted.

Referring to FIG. 16, a semiconductor package 12 may include a package substrate 100, a plurality of first semiconductor chips 200, a second semiconductor chip 300, a plurality of third semiconductor chips 500, a fourth semiconductor chip 600, vertical wires 330, second vertical wires 630, and a molding member 400.

In example embodiments, the package substrate 100 may include first substrate pads 120 for electrical connection with the plurality of first semiconductor chips 200, second substrate pads 122 for electrical connection with the second semiconductor chip 300, third substrate pads 121 for electrical connection with the plurality of third semiconductor chips 500, and fourth substrate pads 123 for electrical connection with the fourth semiconductor chip 600.

The first substrate pads 120 may be arranged to be spaced apart from each other along a second side portion S2 on an upper surface 102 of the package substrate 100. The second substrate pads 122 may be arranged to be spaced apart from each other along a first side portion S1 on the upper surface 102 of the package substrate 100. The third substrate pads 121 may be arranged to be spaced apart from each other along the first side portion S1 on the upper surface 102 of the package substrate 100. The third substrate pads 121 may be arranged closer to the first side portion S1 than the second substrate pads 122. The fourth substrate pads 123 may be arranged to be spaced apart from each other along the second side portion S2 on the upper surface 102 of the package substrate 100. The fourth substrate pads 123 may be arranged closer to the second side portion S2 than the first substrate pads 120. It will be understood that the number, shape, and arrangement of the substrate pads are provided as an example, and the present inventive concept is not limited thereto.

In example embodiments, the plurality of third semiconductor chips 500 and the fourth semiconductor chip 600 may be sequentially stacked in a stepwise manner on the second semiconductor chip 300. The uppermost third semiconductor chip 500b may be offset aligned in an opposite direction (X direction) of a first horizontal direction on the lowermost third semiconductor chip 500a. The fourth semiconductor chip 600 may be offset aligned in the opposite direction (X direction) of the first horizontal direction on the uppermost third semiconductor chip 500b.

For example, two third semiconductor chips 500a, 500b may be sequentially attached on an upper surface 304 of the second semiconductor chip 300 using adhesive films 520a, 520b. The third semiconductor chips 500a, 500b may be arranged such that a second surface 504, e.g., an inactive surface, opposite to a first surface 502 on which third chip pads 510a, 510b are formed, faces the package substrate 100.

In example embodiments, the uppermost third semiconductor chip 500b may include a fifth region, e.g., an overhang region PR3 protruding from one side of the fourth semiconductor chip 600 disposed on the uppermost third semiconductor chip 500b, and a sixth region, e.g., an overhang region OR3 overlapping the fourth semiconductor chip. The third chip pads 510b may include a plurality of fifth bonding pads 512 and a plurality of sixth bonding pads 514.

The plurality of fifth bonding pads 512 may be arranged in an edge region along one side (second side surface) of the uppermost third semiconductor chip 500b on the upper surface, e.g., the front surface 502, of the overhang region PR3 of the uppermost third semiconductor chip 500b. The plurality of fifth bonding pads 512 may be arranged to be spaced apart from each other in the second direction (Y direction) on the first surface 502 of the third semiconductor chip 500b. The plurality of sixth bonding pads 514 may be arranged in an array form on the upper surface, e.g., the front surface 502 of the overlapping region OR3 of the uppermost third semiconductor chip 500b.

The third semiconductor chips 500 may be electrically connected to the package substrate 100 by bonding wires 530 as conductive connecting members. In particular, the third chip pads 510a of the lowermost third semiconductor chip 500a and the plurality of fifth bonding pads 512 of the uppermost third semiconductor chip 500b may be electrically connected to the third substrate pads 121 on the upper surface 102 of the package substrate 100 by the bonding wires 530.

In example embodiments, the second vertical wires 630 as vertical conductive structures may extend vertically on the fourth substrate pads 123 of the package substrate 100 by a desired and/or alternatively predetermined length, respectively. The second vertical wires 630 may be spaced apart from each other along the second side portion S2 on the fourth substrate pads 123 of the package substrate 100. The length of the second vertical wire 630 may be greater than or equal to the height of the uppermost third semiconductor chip 500b from the package substrate 100.

The second vertical wire 630 may include a wire body extending in a vertical direction, a first bonding end portion provided at a first end portion of the wire body and bonded to the fourth substrate pad 123, and a second bonding end portion provided at a second end portion of the wire body. The second vertical wire 630 may be substantially the same as or similar to the vertical wire 330.

In example embodiments, the fourth semiconductor chip 600 may be mounted on the uppermost third semiconductor chip 500b via conductive bumps 620. The conductive bumps 620 may include solder bumps.

The fourth semiconductor chip 600 may be the same type of chip as the third semiconductor chip 500 or a different type of chip from the third semiconductor chip 500. For example, the third and fourth semiconductor chips may include memory chips including memory circuits. For example, the third and fourth semiconductor chips may include volatile memory devices such as SRAM devices, DRAM devices, etc., and non-volatile memory devices such as flash memory devices, PRAM devices, MRAM devices, RRAM devices, etc.

In example embodiments, the fourth semiconductor chip 600 may be stacked in a stepwise manner on the uppermost third semiconductor chip 500b. The fourth semiconductor chip 600 may be offset aligned in the opposite direction (X direction) of the first horizontal direction on the uppermost third semiconductor chip 500b. The fourth semiconductor chip 600 may include a seventh region, e.g., an overhang region PR4, protruding from one side (first side surface) of the uppermost third semiconductor chip 500b disposed below, and an eighth region, e.g., an overlapping region OR4, overlapping with the uppermost third semiconductor chip 500a.

The fourth semiconductor chip 600 may be arranged such that a first surface 602 on which fourth chip pads 610 are formed faces the package substrate 100. The first surface 602 of the fourth semiconductor chip 600 and the first surface 502 of the uppermost third semiconductor chip 500b may face each other. The fourth chip pads 610 may include a plurality of seventh bonding pads 612 and a plurality of eighth bonding pads 614. The fourth semiconductor chip may have a second surface 604 opposite the first surface 602 such that the second surface 604 may face away from the package substrate 100.

The plurality of seventh bonding pads 612 may be arranged in an edge region along one side of the fourth semiconductor chip 600 on a lower surface, e.g., the front surface 602 of the overhang region PR4 of the fourth semiconductor chip 600. The plurality of seventh bonding pads 612 may be arranged to be spaced apart from each other in the second direction (Y direction) on the first surface 602 of the fourth semiconductor chip 600 so as to respectively correspond to the second bonding end portions of the second vertical wires 630.

The plurality of eighth bonding pads 614 may be arranged in an array form on the lower surface, e.g., the front surface 602 of the overlapping region OR4 of the fourth semiconductor chip 600. The plurality of eighth bonding pads 614 may be arranged to be spaced apart from each other on the first surface 602 of the fourth semiconductor chip 600 so as to correspond to the plurality of sixth bonding pads 514 of the uppermost third semiconductor chip 500b, respectively.

The fourth semiconductor chip 600 may be mounted on the uppermost third semiconductor chip 500b in a flip chip manner. The conductive bumps 620 may include a plurality of third conductive bumps 622 and a plurality of fourth conductive bumps 634.

The third conductive bumps 622 may be provided on the plurality of seventh bonding pads 612 of the fourth semiconductor chip 600, respectively. The third conductive bumps 622 may surround upper portions of the second vertical wires 630, e.g., at least portions of the second bonding end portions, respectively. The third conductive bumps 622 may be in contact with the second bonding end portions of the second vertical wires 630, respectively. The second vertical wire 630 may extend from the third conductive bump 622 to the fourth substrate pad 123 of the package substrate 100. Accordingly, the second vertical wire 630 may be electrically connected to the seventh bonding pad 612 by the third conductive bump 622, and the fourth semiconductor chip 600 may be electrically connected to the package substrate 100 by the second vertical wire 630.

The fourth conductive bumps 624 may be provided on the eighth bonding pads 614 of the fourth semiconductor chip 600, respectively. The fourth conductive bumps 624 may be interposed between the eighth bonding pads 614 of the second semiconductor chip 600 and the sixth bonding pads 514 of the third uppermost semiconductor chip 500b, respectively. The fourth conductive bumps 624 may be used as dummy bumps for bonding the fourth semiconductor chip 600 to the first uppermost semiconductor chip 500b. The plurality of sixth bonding pads 514 of the third uppermost semiconductor chip 500b and the plurality of eighth bonding pads 614 of the fourth semiconductor chip 600 may be dummy pads to which no electrical signals are transmitted. Alternatively, the plurality of sixth bonding pads 514 and the plurality of eighth bonding pads 614 may be signal transmission pads through which electrical signals are transmitted, and in this case, the uppermost third semiconductor chip 500b and the fourth semiconductor chip 600 may be electrically connected by the fourth conductive bump 624.

The bonding wire 530 may have a third height as a maximum height from the upper surface 102 of the package substrate 100, and the fourth semiconductor chip 600 may have a fourth height greater than the third height from the upper surface 102 of the package substrate 100.

In example embodiments, the molding member 400 may cover the plurality of first semiconductor chips 200, the second semiconductor chip 300, the plurality of third semiconductor chips 500, the fourth semiconductor chip 600, the bonding wires 230, 530, the vertical wires 330, and the second vertical wires 630 on the upper surface 102 of the package substrate 100.

Hereinafter, a method of manufacturing the semiconductor package of FIG. 16 will be explained.

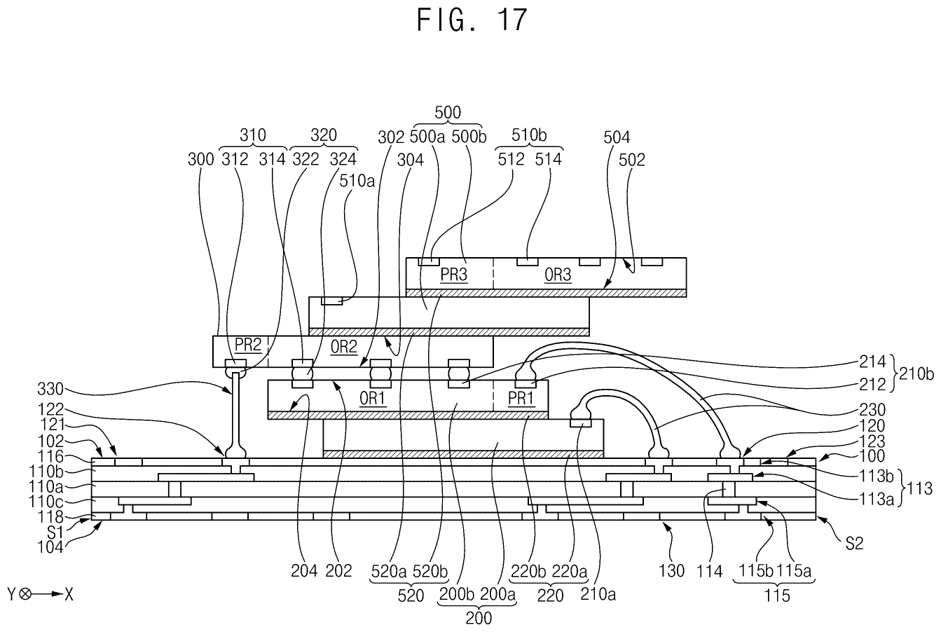

FIGS. 17 to 20 are cross-sectional views illustrating a method for manufacturing a semiconductor package in accordance with example embodiments.

Referring to FIG. 17, processes the same as or similar to the processes described with reference to FIGS. 4 to 13 may be performed to sequentially stack a plurality of first semiconductor chips 200 and a second semiconductor chip 300 on a package substrate 100 and electrically connect the plurality of first semiconductor chips 200 to the package substrate 100 using bonding wires 230, and to electrically connect the second semiconductor chip 300 to the package substrate 100 using vertical wires 330. Then, processes the same as or similar to the processes described with reference to FIGS. 4 and 5 may be performed to sequentially stack a plurality of third semiconductor chips 500 on the second semiconductor chip 300.

In example embodiments, the package substrate 100 may have first substrate pads 120 for electrical connection with the plurality of first semiconductor chips 200, second substrate pads 122 for electrical connection with the second semiconductor chip 300, third substrate pads 121 for electrical connection with the plurality of third semiconductor chips 500, and fourth substrate pads 123 for electrical connection with a fourth semiconductor chip 600.

The first substrate pads 120 may be arranged to be spaced apart from each other along a second side portion S2 on an upper surface 102 of the package substrate 100. The second substrate pads 122 may be arranged to be spaced apart from each other along a first side portion S1 on the upper surface 102 of the package substrate 100. The third substrate pads 121 may be arranged to be spaced apart from each other along the first side portion S1 on the upper surface 102 of the package substrate 100. The third substrate pads 121 may be arranged closer to the first side portion S1 than the second substrate pads 122. The fourth substrate pads 123 may be arranged to be spaced apart from each other along the second side portion S2 on the upper surface 102 of the package substrate 100. The fourth substrate pads 123 may be arranged closer to the second side portion S2 than the first substrate pads 120. The number, shape, and arrangement of the substrate pads are provided as examples, and it will be understood that the present inventive concept is not limited thereto. In example embodiments, the plurality of third semiconductor chips 500 may be sequentially stacked in a stepwise manner on the second semiconductor chip 300. The lowermost third semiconductor chip 500a may be offset aligned in an opposite direction (X direction) of the first horizontal direction on the second semiconductor chip 300. The uppermost third semiconductor chip 500b may be offset aligned in the opposite direction (X direction) of the first horizontal direction on the lowermost third semiconductor chip 500a.

For example, two third semiconductor chips 500a, 500b may be sequentially attached to an upper surface 304 of the second semiconductor chip 300 using adhesive films 520a, 520b. The third semiconductor chips 500a, 500b may be arranged such that a second surface 504, e.g., an inactive surface, which is opposite to a first surface 502 on which third chip pads 510a, 510b are formed, faces the package substrate 100.

In example embodiments, the uppermost third semiconductor chip 500b may include a fifth region, e.g., an overhang region PR3 protruding from one side of the fourth semiconductor chip 600 to be disposed on the uppermost third semiconductor chip 500b, and a sixth region, e.g., an overlapping region OR3 overlapping the fourth semiconductor chip. The third chip pads 510b may include a plurality of fifth bonding pads 512 and a plurality of sixth bonding pads 514.

The plurality of fifth bonding pads 512 may be arranged on an edge region along one side (second side surface) of the uppermost third semiconductor chip 500b on an upper surface, e.g., the front surface 502 of the overhang region PR3 of the uppermost third semiconductor chip 500b. The plurality of fifth bonding pads 512 may be arranged to be spaced apart from each other in the second direction (Y direction) on the first surface 502 of the third semiconductor chip 500b. The plurality of sixth bonding pads 514 may be arranged in an array form on the upper surface, e.g., the front surface 502 of the overlapping region OR3 of the uppermost third semiconductor chip 500b.

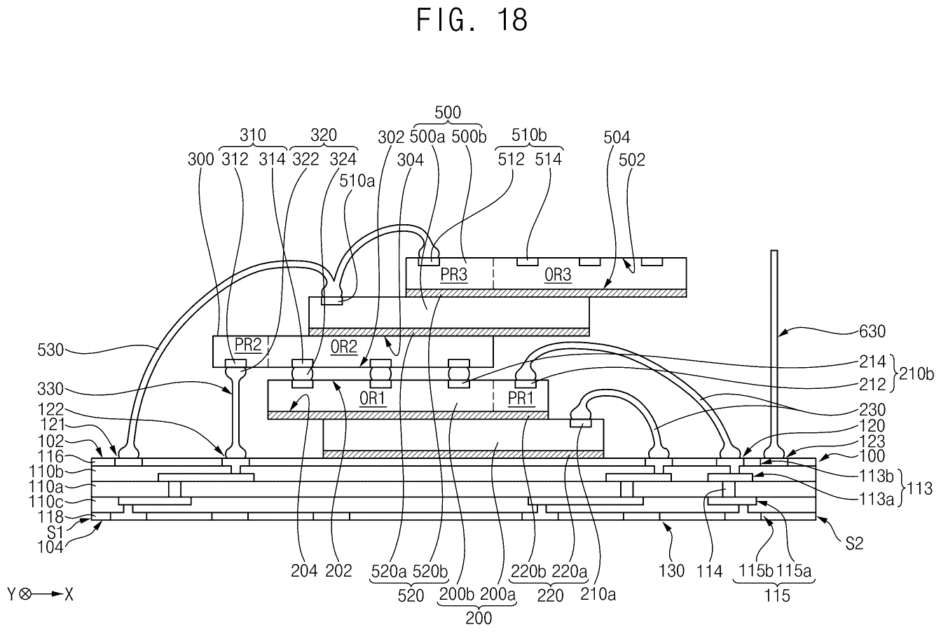

Referring to FIG. 18, processes the same as or similar to the processes described with reference to FIGS. 6 to 10 may be performed to electrically connect the plurality of third semiconductor chips 500 to the package substrate 100 by conductive connecting members 530 and form a plurality of second vertical wires 630 as vertical conductive structures on the fourth substrate pads 123 of the package substrate 100.

As illustrated in FIG. 18, a wire bonding process may be performed to electrically connect the third chip pads 510a of the lowermost third semiconductor chip 500a and the plurality of fifth bonding pads 512 of the uppermost third semiconductor chip 500b to the third substrate pads 121 on the upper surface 102 of the package substrate 100 by bonding wires 530.

Then, the second vertical wires 630 may be formed on the fourth substrate pads 123 of the package substrate 100 to extend upwardly to a desired and/or alternatively predetermined length by a wire bonding process. The length of the second vertical wire 630 may be greater than or equal to a height of the uppermost third semiconductor chip 500b from the package substrate 100.

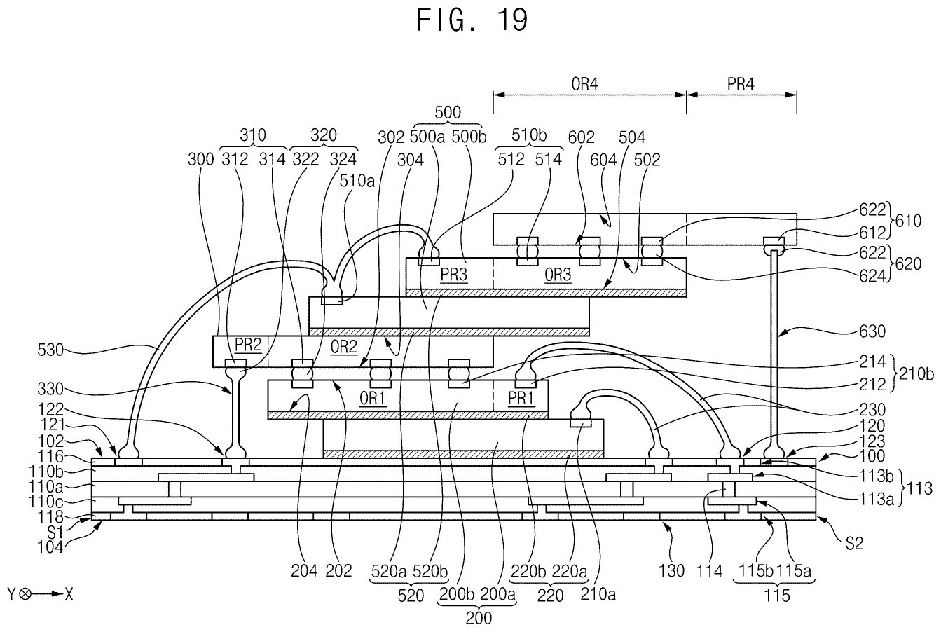

Referring to FIG. 19, processes the same as or similar to the processes described with reference to FIGS. 11 to 13 may be performed to dispose a fourth semiconductor chip 600 on the uppermost third semiconductor chip 500b via conductive bumps 620.

In example embodiments, the fourth semiconductor chip 600 may be stacked in a stepwise manner on the uppermost third semiconductor chip 500b. The fourth semiconductor chip 600 may be offset aligned in an opposite direction (X direction) of the first horizontal direction on the uppermost third semiconductor chip 500b. The fourth semiconductor chip 600 may include a seventh region, e.g., an overhang region PR4, protruding from one side (first side surface) of the uppermost third semiconductor chip 500b placed below, and an eighth region, e.g., an overhang region OR4, overlapping with the uppermost third semiconductor chip 500a.

The fourth semiconductor chip 600 may be arranged such that a first surface 602 on which fourth chip pads 610 are formed faces the package substrate 100. The first surface 602 of the fourth semiconductor chip 600 and the first surface 502 of the uppermost third semiconductor chip 500b may face each other. The fourth chip pads 610 may include a plurality of seventh bonding pads 612 and a plurality of eighth bonding pads 614.

The plurality of seventh bonding pads 612 may be arranged in an edge region along one side of the fourth semiconductor chip 600 on a lower surface, e.g., the front surface 602 of the overhang region PR4 of the fourth semiconductor chip 600. The plurality of seventh bonding pads 612 may be arranged to be spaced apart from each other in the second direction (Y direction) on the first surface 602 of the fourth semiconductor chip 600 so as to correspond to second bonding end portions of the second vertical wires 630, respectively. The plurality of eighth bonding pads 614 may be arranged in an array form on the lower surface, e.g., the front surface 602 of the overlapping region OR4 of the fourth semiconductor chip 600.

The plurality of eighth bonding pads 614 may be arranged to be spaced apart from each other on the first surface 602 of the fourth semiconductor chip 600 so as to correspond to the plurality of sixth bonding pads 514 of the uppermost third semiconductor chip 500b, respectively.

The fourth semiconductor chip 600 may be mounted on the uppermost third semiconductor chip 500b in a flip chip manner. After the conductive bumps 620 are respectively formed on the fourth chip pads 610 of the fourth semiconductor chip 600, flux may be applied on the conductive bumps 620. Then, the fourth semiconductor chip 600 may be placed on the uppermost third semiconductor chip 500b via the conductive bumps 620, and a soldering process may be performed to bond the conductive bumps 620 to the plurality of sixth bonding pads 514 of the uppermost third semiconductor chip 500b and upper portions of the second vertical wires 630. During the soldering process, an oxide layer on surfaces of the conductive bumps 620 may be removed by the flux, so that the conductive bumps 620 may be bonded to the plurality of sixth bonding pads 514 of the uppermost third semiconductor chip 500b and the upper portions of the second vertical wires 630, respectively.

The conductive bumps 620 may include a plurality of third conductive bumps 622 and a plurality of fourth conductive bumps 634.

The third conductive bumps 622 may be formed on the plurality of seventh bonding pads 612 of the fourth semiconductor chip 600, respectively. The third conductive bumps 622 may be formed to surround the upper portions of the second vertical wires 630, e.g., at least portions of the second bonding end portions. The third conductive bumps 622 may each contact the second bonding end portions of the second vertical wires 630. The second vertical wire 630 may extend from the third conductive bump 622 to the fourth substrate pad 123 of the package substrate 100. Accordingly, the second vertical wire 630 may be electrically connected to the seventh bonding pad 312 by the third conductive bump 622, and the fourth semiconductor chip 600 may be electrically connected to the package substrate 100 by the second vertical wire 630.

The fourth conductive bumps 624 may be formed on the eighth bonding pads 614 of the fourth semiconductor chip 600, respectively. The fourth conductive bumps 624 may be interposed between the eighth bonding pads 614 of the second semiconductor chip 600 and the sixth bonding pads 514 of the uppermost third semiconductor chip 500b. The fourth conductive bumps 624 may be used as bonding dummy bumps for bonding the fourth semiconductor chip 600 to the uppermost first semiconductor chip 500b. The plurality of sixth bonding pads 514 of the uppermost third semiconductor chip 500b and the plurality of eighth bonding pads 614 of the fourth semiconductor chip 600 may be dummy pads to which no electrical signals are transmitted.

Alternatively, the plurality of sixth bonding pads 514 and the plurality of eighth bonding pads 614 may be signal transmission pads through which electrical signals are transmitted, and in this case, the uppermost third semiconductor chip 500b and the fourth semiconductor chip 600 may be electrically connected by the fourth conductive bump 624.

The bonding wire 530 may have a third height as a maximum height from the upper surface 102 of the package substrate 100, and the fourth semiconductor chip 600 may have a fourth height greater than the third height from the upper surface 102 of the package substrate 100.

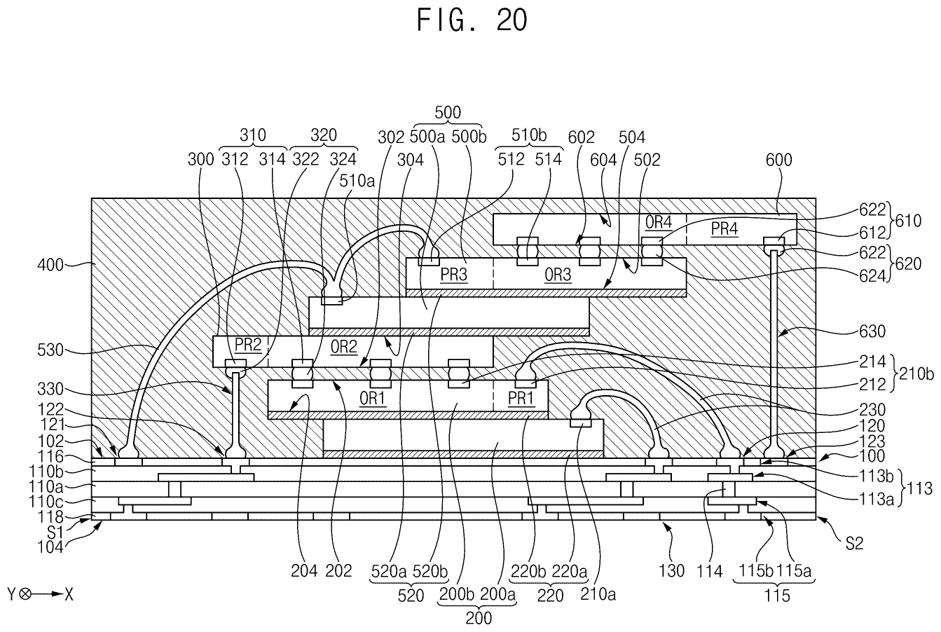

Referring to FIG. 20, a molding member 400 may be formed on the upper surface 102 of the package substrate 100 to cover the plurality of first semiconductor chips 200, the second semiconductor chip 300, the plurality of third semiconductor chips 500, the fourth semiconductor chip 600, the bonding wires 230, 530, the vertical wires 330, and the second vertical wires 630.

In example embodiments, the molding member 400 may be formed on the package substrate 100 by a transfer molding apparatus. The molding member 400 may be formed to completely cover the fourth semiconductor chip 600. The molding member 400 may include a thermosetting resin, for example, an epoxy mold compound EMC.

A gap may be formed between the uppermost first semiconductor chip 200b and the second semiconductor chip 300 by the second conductive bumps 324. At least a portion of the molding member 400 may be formed to surround the plurality of second conductive bumps 324 between the uppermost first semiconductor chip 200b and the second semiconductor chip 300.

A gap may be formed between the uppermost third semiconductor chip 500b and the fourth semiconductor chip 600 by the fourth conductive bumps 624. At least a portion of the molding member 400 may be formed to surround the plurality of fourth conductive bumps 624 between the uppermost third semiconductor chip 500b and the fourth semiconductor chip 600.

Then, external connection members (160, see FIG. 16) may be formed on lower substrate pads 130 on a lower surface 104 of the package substrate 100 to complete the semiconductor package 12 of FIG. 16.

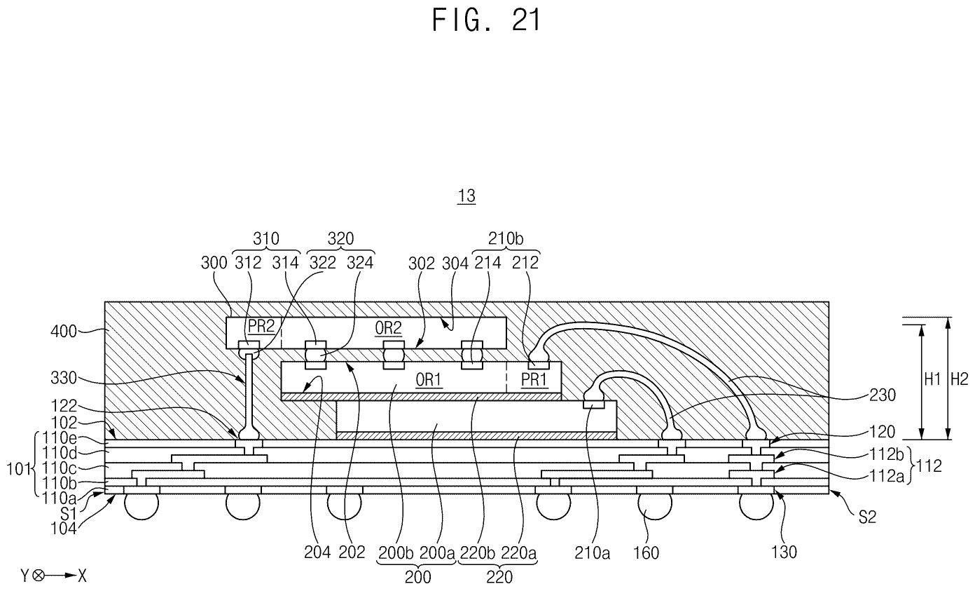

FIG. 21 is a cross-sectional view illustrating a semiconductor package in accordance with example embodiments. The semiconductor package may be substantially the same as or similar to the semiconductor package described with reference to FIGS. 1 to 4 except for a configuration of the package substrate. Thus, same reference numerals will be used to refer to the same or like elements and any further repetitive explanation concerning the above elements will be omitted.

Referring to FIG. 21, a semiconductor package 13 may include a redistribution wiring layer 101, a plurality of first semiconductor chips 200, a second semiconductor chip 300, vertical wires 330, and a molding member 400.

In example embodiments, the redistribution wiring layer 101 may have redistribution wirings 112. The first semiconductor chips 200 and the second semiconductor chips 300 may be stacked on the redistribution wiring layer 101 as a package substrate to be electrically connected to the redistribution wirings 112.

In particular, the redistribution wiring layer 101 may include a plurality of first to fifth lower insulating layers 110a, 110b, 110c, 110d, 110e and redistribution wirings 112 provided within the first to fifth lower insulating layers. The redistribution wirings 112 may include first and second lower redistribution wirings 112a, 112b.

The first to fifth lower insulating layers may include a polymer, a dielectric layer, etc. For example, the first to fifth lower insulating layers may include a photosensitive insulating layer such as a photo imagable dielectric PID. The first to fifth lower insulating layers may be formed by a vapor deposition process, a spin coating process, or the like. The redistribution wirings may include aluminum (Al), copper (Cu), tin (Sn), nickel (Ni), gold (Au), platinum (Pt), or an alloy thereof. The redistribution wirings may be formed by a plating process, an electroless plating process, a vapor deposition process, etc.

In particular, the first lower insulating layer 110a may be provided with a lower substrate pad 130. The lower substrate pad 130 may be a bump pad. The bump pad may include a solder pad or a pillar pad. For example, the lower bonding pad may include copper (Cu), aluminum (Al), tin (Sn), nickel (Ni), gold (Au), platinum (Pt), or an alloy thereof.

The second lower insulating layer 110b may be formed on the first lower insulating layer 110a, and the first lower redistribution wiring 112a may be formed on the second lower insulating layer 110b. The first lower redistribution wiring 112a may be electrically connected to the lower substrate pad 130 through a first opening formed in the second lower insulating layer 110b.

The third lower insulating layer 110c may be formed on the second lower insulating layer 110b, and the second lower redistribution wiring 112b may be formed on the third lower insulating layer 110c. The second lower redistribution wiring 112b may be electrically connected to the first lower redistribution wiring 112a through a second opening formed in the third lower insulating layer 110c.

The fourth lower insulating layer 110d may be formed on the third lower insulating layer 110c, and upper substrate pads 120, 122 may be formed on the fourth lower insulating layer 110d. The upper substrate pads 120, 122 may be electrically connected to the second lower redistribution wiring 112b through a third opening formed in the fourth lower insulating layer 110d.

A solder resist layer 110e as the fifth lower insulating layer may be formed on the fourth lower insulating layer 110d and may expose at least portions of the upper substrate pads 120, 122. The solder resist film 150 may serve as a passivation layer.

The upper substrate pads may include first substrate pads 120 for electrical connection with the plurality of first semiconductor chips 200 and second substrate pads 122 for electrical connection with the second semiconductor chip 300. The first substrate pads 120 may be arranged to be spaced apart from each other along a first side portion S1 on the upper surface 102 of the redistribution wiring layer 101. The second substrate pads 122 may be arranged to be spaced apart from each other along a second side portion S2 opposite to the first side portion on the upper surface 102 of the redistribution wiring layer 101. It will be understood that the number, arrangement, etc. of the lower insulating layers and the lower redistribution wirings of the redistribution wiring layer are provided as examples, and the present inventive concept is not limited thereto.

In example embodiments, the plurality of first semiconductor chips 200 may be sequentially stacked in a stepwise manner on the redistribution wiring layer 101. For example, two first semiconductor chips 200a, 200b may be sequentially attached on an upper surface 102 of the redistribution wiring layer 101 using adhesive films 220a, 220b.

The first semiconductor chips 200 may be electrically connected to the redistribution wiring layer 101 by bonding wires 230 as conductive connecting members. In particular, first chip pads 210a of the lowermost first semiconductor chip 200a and a plurality of first bonding pads 212 of the uppermost first semiconductor chip 200b may be electrically connected to the first substrate pads 120 on the upper surface 102 of the redistribution wiring layer 101 by the bonding wires 230.

In example embodiments, the vertical wires 330 as vertical conductive structures may extend vertically on the second substrate pads 122 of the redistribution wiring layer 101 by a desired and/or alternatively predetermined length, respectively. The vertical wires 330 may be spaced apart from each other along the first side portion S1 on the second substrate pads 122 of the redistribution wiring layer 101. The length of the vertical wire 330 may be greater than or equal to a height of the uppermost first semiconductor chip 200b from the redistribution wiring layer 101.

In example embodiments, the second semiconductor chip 300 may be mounted on the uppermost first semiconductor chip 200b via conductive bumps 320. The conductive bumps 320 may include solder bumps.

The second semiconductor chip 300 may be stacked in a stepwise manner on the uppermost first semiconductor chip 200b. The second semiconductor chip 300 may be offset aligned in a first horizontal direction (−X direction) on the uppermost first semiconductor chip 200b.

The second semiconductor chip 300 may be mounted on the uppermost first semiconductor chip 200b in a flip chip manner. The conductive bumps 320 may include a plurality of first conductive bumps 322 and a plurality of second conductive bumps 324. The first conductive bumps 322 may be solder bumps for bonding with the vertical wires 330, and the second conductive bumps 324 may be solder bumps for bonding with the bonding pads of the uppermost first semiconductor chip 200b.

The first conductive bumps 322 may be formed on a plurality of third bonding pads 312 of the second semiconductor chip 300, respectively. The first conductive bumps 322 may be formed to surround upper portions of the vertical wires 330, that is, at least portions of second bonding end portions. The first conductive bumps 322 may be in contact with the second bonding end portions of the vertical wires 330, respectively. The vertical wires 330 may extend from the first conductive bumps 322 to the second substrate pads 122 of the redistribution wiring layer 101. Accordingly, the vertical wire 330 may be electrically connected to the third bonding pad 312 by the first conductive bump 322, and the second semiconductor chip 300 may be electrically connected to the redistribution wiring layer 101 by the vertical wire 330.

The second conductive bumps 324 may be formed on a plurality of fourth bonding pads 314 of the second semiconductor chip 300. The second conductive bumps 324 may be interposed between the fourth bonding pads 314 of the second semiconductor chip 300 and the second bonding pads 214 of the uppermost first semiconductor chip 200b. The second conductive bumps 324 may be used as bonding dummy bumps for bonding the second semiconductor chip 300 to the uppermost first semiconductor chip 200b. The plurality of second bonding pads 214 of the uppermost first semiconductor chip 200b and the plurality of fourth bonding pads 314 of the second semiconductor chip 300 may be dummy pads to which no electrical signal is transmitted.

In example embodiments, the molding member 400 may cover the plurality of first semiconductor chips 200, the second semiconductor chips 300, the bonding wires 230, and the conductive wires 330 on the upper surface 102 of the redistribution wiring layer 101.

Hereinafter, a method for manufacturing the semiconductor package of FIG. 21 will be described.

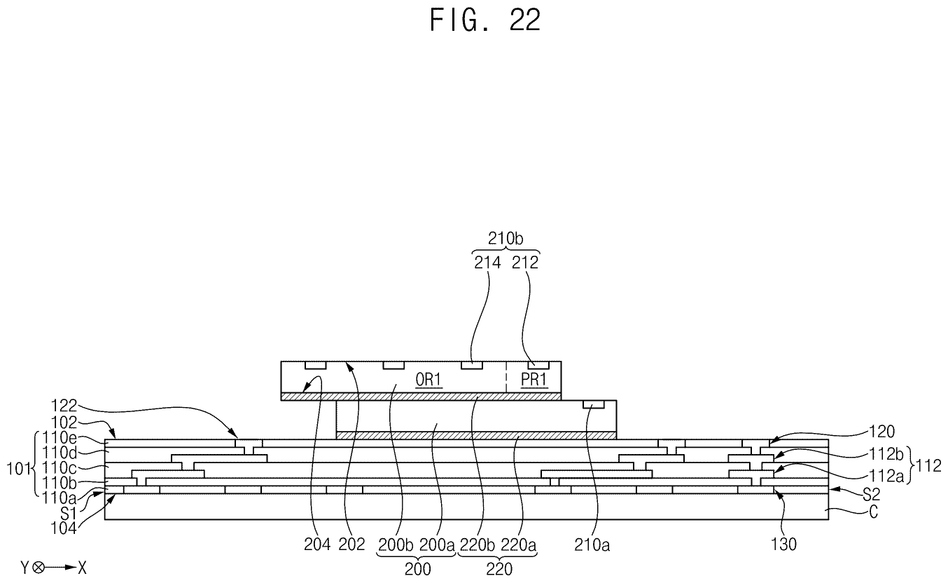

FIGS. 22 to 25 are cross-sectional views illustrating a method of manufacturing a semiconductor package in accordance with example embodiments.

Referring to FIG. 22, a redistribution wiring layer 101 as a package substrate may be formed on a carrier substrate C, and processes the same as or similar to the processes described with reference to FIGS. 4 and 5 may be performed to sequentially stack a plurality of first semiconductor chips 200 on the redistribution wiring layer 101.

In example embodiments, the carrier substrate C may be provided as a base substrate on which a plurality of semiconductor chips are stacked on the redistribution wiring layer and a molding member is formed. The carrier substrate C may have a shape corresponding to a wafer on which semiconductor manufacturing processes are performed. For example, the carrier substrate C may include a glass substrate, a silicon substrate, a non-metallic or metallic plate, etc.

The carrier substrate C may include a package region in which the semiconductor chips are arranged and a cutting region surrounding the package region. As described below, the molding member and the redistribution wiring layer formed on the carrier substrate C may be cut along the cutting region that divides the plurality of package regions PR to be individualized.

In example embodiments, a first lower insulating layer 110a having lower substrate pads 130 formed therein may be formed on the carrier substrate C. Although not illustrated in the figures, after forming a release film, a barrier metal layer, a seed layer, and the first lower insulating layer on the carrier substrate C, the first lower insulating layer may be patterned to form openings that expose first substrate pad regions. Then, a plating process may be performed on the seed layer to form the lower substrate pads 130 within the openings. For example, the first lower insulating layer 110a may include a polymer, a dielectric layer, or the like. The first lower insulating layer 110a may include a photosensitive insulating material PID, an insulating layer such as ABF, or the like. The first lower insulating layer may be formed by a spin coating process, a vapor deposition process, or the like.

The lower substrate pad 130 may be a bump pad. The bump pad may include a solder pad or a pillar pad. For example, the lower substrate pad may include copper (Cu), aluminum (Al), tin (Sn), nickel (Ni), gold (Au), platinum (Pt), or an alloy thereof.

Then, a second lower insulating layer 110a is formed on the first lower insulating layer 110a to cover the lower substrate pads 130, and then, the second lower insulating layer 110a may be patterned to form first openings that expose at least portions of the lower substrate pads 130. For example, the second lower insulating layer 110b may include an insulating material that is the same as or similar to the first lower insulating layer 110a.

Then, first lower redistribution wirings 112a may be formed on the second lower insulating layer 110b to be electrically connected to the lower substrate pads 130 through the first openings.

For example, the first lower redistribution wiring 112a may be formed by forming a seed layer on a portion of the second lower insulating layer 110b and within the first opening, and then patterning the seed layer and performing an electroplating process. Accordingly, at least a portion of the first lower redistribution wiring 112a may be electrically connected to the lower substrate pad 130 through the first opening. For example, the first lower redistribution wiring may include copper (Cu), aluminum (Al), tin (Sn), nickel (Ni), gold (Au), platinum (Pt), or an alloy thereof.

Similarly, a third lower insulating layer 110b may be formed on the second lower insulating layer 110b to cover the first lower redistribution wirings 112a, and the third lower insulating layer 110b may be patterned to form second openings that expose at least portions of the first lower redistribution wirings 112a. Then, second lower redistribution wirings 112b may be formed on the third lower insulating layer 110c to be electrically connected to the first lower redistribution wirings 112a through the second openings.

Then, a fourth lower insulating layer 110d may be formed on the third lower insulating layer 110c covering the second lower redistribution wirings 112b, and the fourth lower insulating layer 110d may be patterned to form third openings that expose at least portions of the second lower redistribution wirings 112b. Then, upper substrate pads 120, 122 may be formed on the fourth lower insulating layer 110d to be electrically connected to the second lower redistribution wirings 112b through the third openings.

Then, a fifth lower insulating layer 110e may be formed on the fourth lower insulating layer 110d to expose the upper substrate pads 120, 122.

Accordingly, the redistribution wiring layer 101 having the first to fifth lower insulating layers 110a, 110b, 110c, 110d, 110e may be formed. The redistribution wiring layer 101 may include redistribution wirings 112 stacked in at least two layers. The redistribution wirings 112 may include first and second lower redistribution wirings 112a, 112b that are vertically stacked. The upper substrate pads 120, 122 may be exposed from an upper surface 102 of the redistribution wiring layer 101. The lower substrate pads 130 may be exposed from a lower surface 104 of the redistribution wiring layer 101. For example, a thickness of the redistribution wiring layer 101 may be within a range of 10 μm to 50 μm.

The upper substrate pads 120, 122 may be formed on the upper surface 102 of the redistribution wiring layer 101 and on the uppermost redistribution wirings 112b. For example, the upper substrate pads 120, 122 may have a multilayer structure. The upper substrate pads 120, 122 may include a bonding pad pattern and a plating pad pattern formed on the bonding pad pattern. The bonding pad pattern may include copper (Cu), and the plating pad pattern may include nickel (Ni), gold (Au), titanium (Ti), etc. The upper substrate pads may include first substrate pads 120 for electrical connection with a plurality of first semiconductor chips 200 and second substrate pads 122 for electrical connection with a second semiconductor chip described below. The first substrate pads 120 may be arranged to be spaced apart from each other along a first side portion S1 of the package region on the upper surface 102 of the redistribution wiring layer 101. The second substrate pads 122 may be arranged to be spaced apart from each other along a second side portion S2 opposite to the first side portion on the upper surface 102 of the redistribution wiring layer 101.

Then, two first semiconductor chips 200a, 200b may be sequentially stacked on the redistribution wiring layer 101. The first semiconductor chips 200a, 200b may be sequentially attached on the upper surface 102 of the redistribution wiring layer 101 using adhesive layers 220a, 220b. The first semiconductor chips 200a, 200b may be sequentially attached on the redistribution wiring layer 101 using the adhesive films such as a die attach film (DAF) by a die attach process.

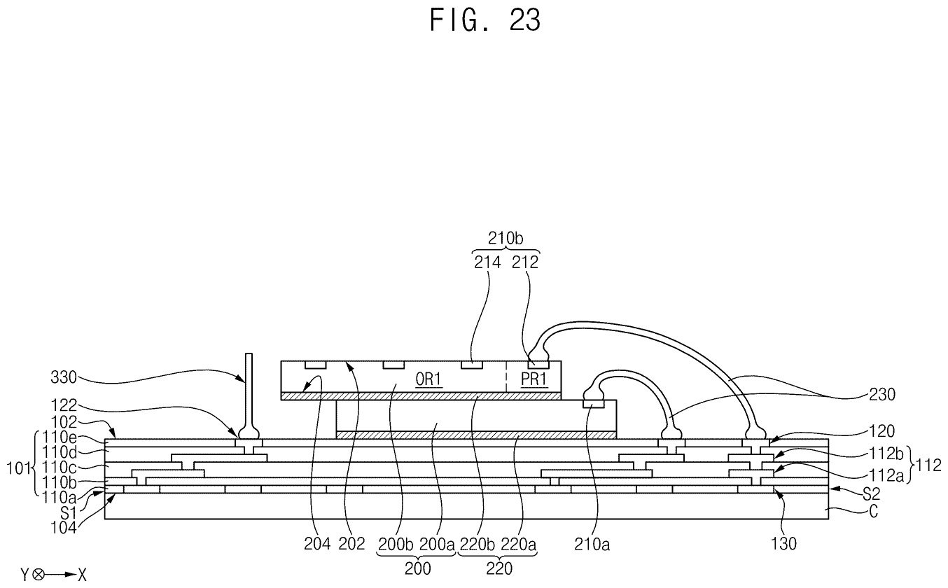

Referring to FIG. 23, processes the same as or similar to the processes described with reference to FIGS. 6 to 10 may be performed to electrically connect the plurality of first semiconductor chips 200 to the redistribution wiring layer 101 by conductive connecting members (bonding wires) 230 and to form a plurality of vertical wires 330 as vertical conductive structures on the second substrate pads 122 of the redistribution wiring layer 101.

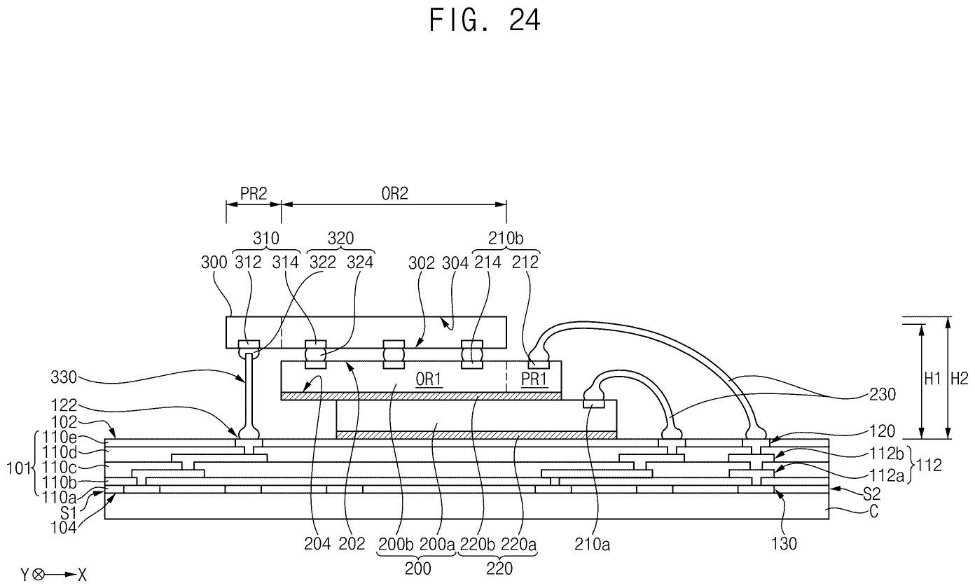

Referring to FIG. 24, processes the same as or similar to the processes described with reference to FIGS. 11 to 13 may be performed to place a second semiconductor chip 300 on the uppermost first semiconductor chip 200b using conductive bumps 320.

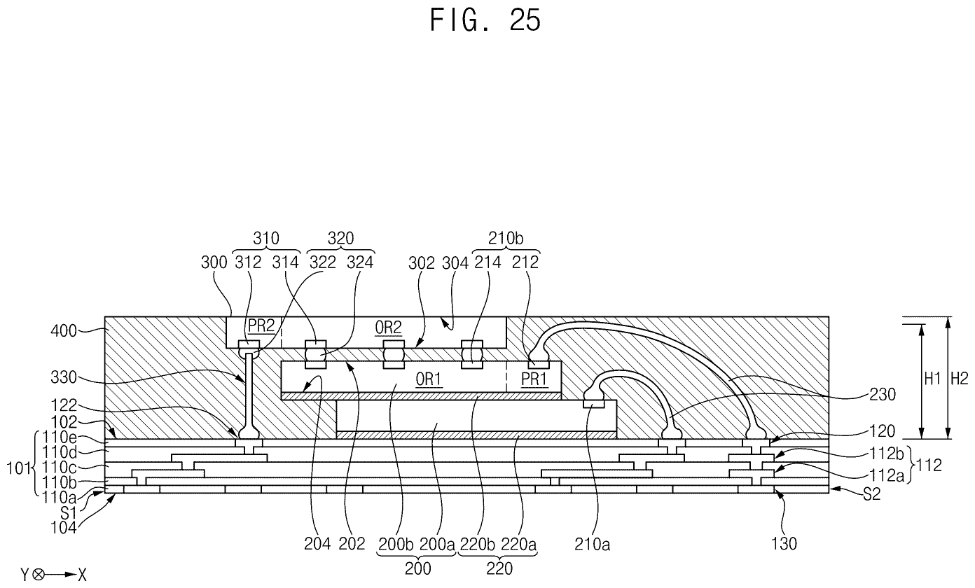

Referring to FIG. 25, processes the same as or similar to the processes described with reference to FIG. 14 may be performed to form a molding member 400 on the upper surface 102 of the redistribution wiring layer 101 to cover the plurality of first semiconductor chips 200, the second semiconductor chip 300, the bonding wires 230, and the vertical wires 330.

Then, the carrier substrate C may be removed from the redistribution wiring layer 101 and external connection members (160, see FIG. 21) may be formed on the lower substrate pads 130 on an outer surface, e.g., the lower surface 104 of the redistribution wiring layer 101.

Then, the redistribution wiring layer 101 may be individualized through a sawing process to complete the semiconductor package 13 of FIG. 21.

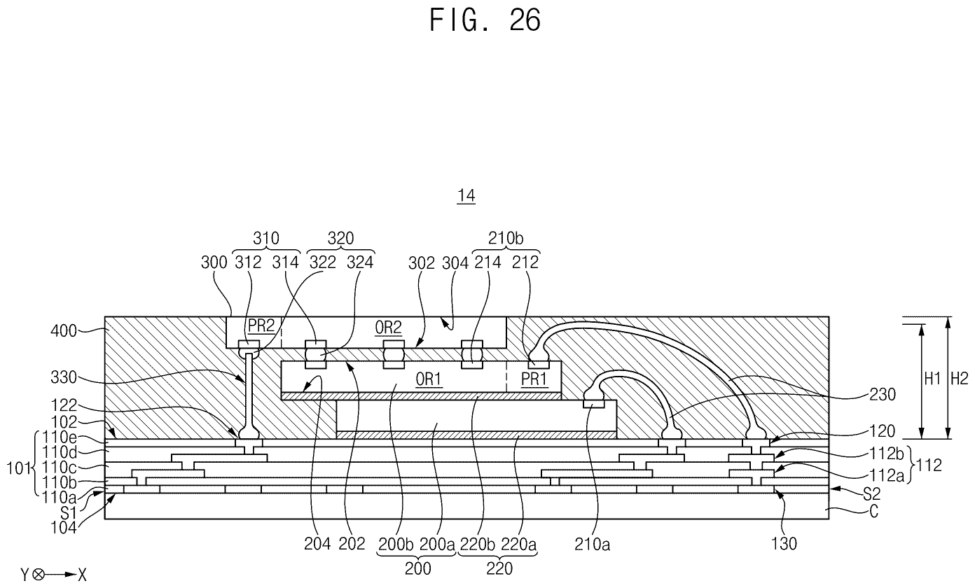

FIG. 26 is a cross-sectional view illustrating a semiconductor package in accordance with example embodiments. The semiconductor package may be substantially the same as or similar to the semiconductor package described with reference to FIG. 21 except for a configuration of a molding member. Thus, same reference numerals will be used to refer to the same or like elements and any further repetitive explanation concerning the above elements will be omitted.

Referring to FIG. 26, a molding member 400 of a semiconductor package 14 may cover a plurality of first semiconductor chips 200, a second semiconductor chip 300, bonding wires 230, and conductive wires 330 on an upper surface 102 of a redistribution wiring layer 101.

In example embodiments, the molding member 400 may expose at least a portion of an upper surface, e.g., a second surface 304 of the second semiconductor chip 300. Since the at least a portion of the second surface 304 of the second semiconductor chip 300 is exposed, heat dissipation characteristics from the second semiconductor chip 300 to the outside may be improved.

In addition, since the second surface 304 of the second semiconductor chip 300 and an upper surface of the molding member 400 are positioned on the same plane, the overall thickness of the package may be reduced.

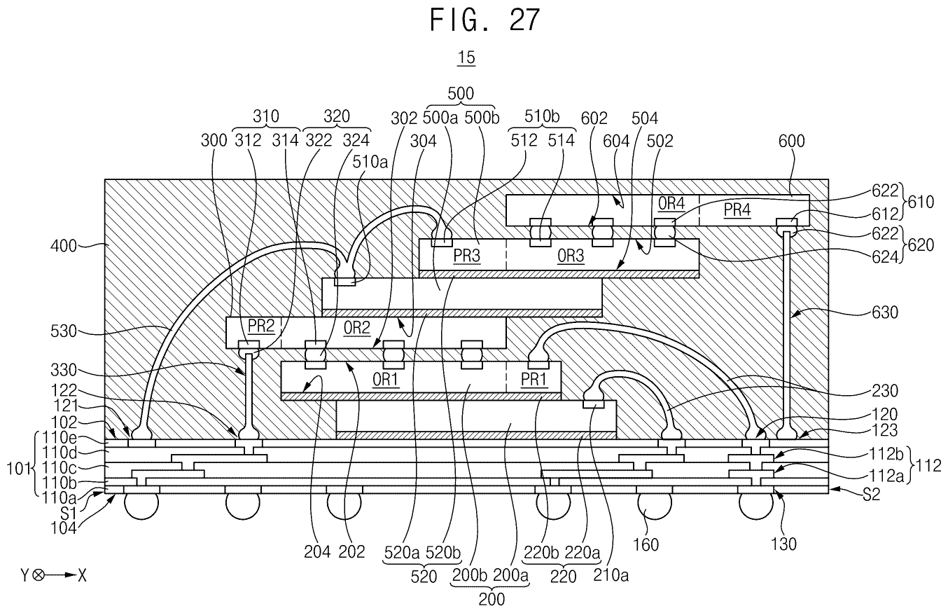

FIG. 27 is a cross-sectional view illustrating a semiconductor package in accordance with example embodiments. The semiconductor package may be substantially the same as or similar to the semiconductor package described with reference to FIG. 21 except for additional configurations of a plurality of third semiconductor chips, a fourth semiconductor chip and second vertical wires. Thus, same reference numerals will be used to refer to the same or like elements and any further repetitive explanation concerning the above elements will be omitted.

Referring to FIG. 27, a semiconductor package 15 may include a redistribution wiring layer 101, a plurality of first semiconductor chips 200, a second semiconductor chip 300, a plurality of third semiconductor chips 500, a fourth semiconductor chip 600, vertical wires 330, second vertical wires 630, and a molding member 400.

In example embodiments, the redistribution wiring layer 101 may include first substrate pads 120 for electrical connection with the plurality of first semiconductor chips 200, second substrate pads 122 for electrical connection with the second semiconductor chip 300, third substrate pads 121 for electrical connection with the plurality of third semiconductor chips 500, and fourth substrate pads 123 for electrical connection with the fourth semiconductor chip 600.

The first substrate pads 120 may be arranged to be spaced apart from each other along a second side portion S2 on an upper surface 102 of the redistribution wiring layer 101. The second substrate pads 122 may be arranged to be spaced apart from each other along a first side portion S1 on the upper surface 102 of the redistribution wiring layer 101. The third substrate pads 121 may be arranged to be spaced apart from each other along the first side portion S1 on the upper surface 102 of the redistribution wiring layer 101. The third substrate pads 121 may be arranged closer to the first side portion S1 than the second substrate pads 122. The fourth substrate pads 123 may be arranged to be spaced apart from each other along the second side portion S1 on the upper surface 102 of the redistribution wiring layer 101. The fourth substrate pads 123 may be arranged closer to the second side portion S2 than the first substrate pads 120. It will be understood that the number, shape, and arrangement of the substrate pads are provided as examples, and the present inventive concept is not limited thereto.

In example embodiments, the plurality of third semiconductor chips 500 and the fourth semiconductor chip 600 may be sequentially stacked in a stepwise manner on the second semiconductor chip 300. For example, two third semiconductor chips 500a, 500b may be sequentially attached on an upper surface 304 of the second semiconductor chip 300 using adhesive films 520a, 520b.

The third semiconductor chips 500 may be electrically connected to the redistribution wiring layer 101 by bonding wires 530 as conductive connecting members. In particular, third chip pads 510a of the lowermost third semiconductor chip 500a and a plurality of first bonding pads 512 of the uppermost third semiconductor chip 500b may be electrically connected to the third substrate pads 121 on the upper surface 102 of the redistribution wiring layer 101 by the bonding wires 530.

In example embodiments, the second vertical wires 630 as vertical conductive structures may extend vertically on the fourth substrate pads 123 of the redistribution wiring layer 101 by a desired and/or alternatively predetermined length, respectively. The second vertical wires 630 may be spaced apart from each other along the second side portion S2 on the fourth substrate pads 123 of the redistribution wiring layer 101. The length of the second vertical wires 630 may be greater than or equal to a height of the uppermost third semiconductor chip 500b from the redistribution wiring layer 101.

In example embodiments, the fourth semiconductor chip 600 may be mounted on the uppermost third semiconductor chip 500b via conductive bumps 620. The conductive bumps 620 may include solder bumps

The fourth semiconductor chip 600 may be stacked in a stepwise manner on the uppermost third semiconductor chip 500b. The fourth semiconductor chip 600 may be offset aligned in an opposite direction (X direction) of a first horizontal direction on the uppermost third semiconductor chip 500b.

The fourth semiconductor chip 600 may be mounted on the uppermost third semiconductor chip 500b in a flip chip manner. The conductive bumps 620 may include a plurality of third conductive bumps 622 and a plurality of fourth conductive bumps 634. The third conductive bumps 622 may be solder bumps for bonding with the second vertical wires 630, and the fourth conductive bumps 624 may be solder bumps for bonding with the bonding pads of the uppermost third semiconductor chip 500b.

The third conductive bumps 622 may be formed on a plurality of seventh bonding pads 612 of the fourth semiconductor chip 600, respectively. The third conductive bumps 622 may surround upper portions of the second vertical wires 630, e.g., at least portions of second bonding end portions. The third conductive bumps 622 may be in contact with the second bonding end portions of the second vertical wires 630, respectively. The second vertical wire 630 may extend from the third conductive bump 622 to the fourth substrate pad 123 of the redistribution wiring layer 101. Accordingly, the second vertical wire 630 may be electrically connected to the seventh bonding pad 612 by the third conductive bump 622, and the fourth semiconductor chip 600 may be electrically connected to the redistribution wiring layer 101 by the second vertical wire 630.

The fourth conductive bumps 624 may be formed on eighth bonding pads 614 of the fourth semiconductor chip 600, respectively. The fourth conductive bumps 624 may be interposed between the eighth bonding pads 614 of the second semiconductor chip 600 and sixth bonding pads 514 of the third uppermost semiconductor chip 500b, respectively. The fourth conductive bumps 624 may be used as dummy bumps for bonding the fourth semiconductor chip 600 to the first uppermost semiconductor chip 500b. The plurality of sixth bonding pads 514 of the third uppermost semiconductor chip 500b and the plurality of eighth bonding pads 614 of the fourth semiconductor chip 600 may be dummy pads to which no electrical signal is transmitted.

In example embodiments, the molding member 400 may cover the plurality of first semiconductor chips 200, the second semiconductor chip 300, the plurality of third semiconductor chips 500, the fourth semiconductor chip 600, the bonding wires 230, 530, the vertical wires 330, and the second vertical wires 630 on the upper surface 102 of the rewiring layer 101.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of embodiments of inventive concepts. Accordingly, all such modifications are intended to be included within the scope of example embodiments as defined in the claims.

1. A semiconductor package, comprising:
a package substrate;
a plurality of first semiconductor chips sequentially stacked on an upper surface of the package substrate, each of the plurality of first semiconductor chips including a first surface and a second surface, the first surface including first chip pads and being opposite the second surface, the second surface facing the package substrate;
a second semiconductor chip on an uppermost first semiconductor chip among the plurality of first semiconductor chips, a first surface of the second semiconductor chips including second chip pads and facing the package substrate, the second semiconductor chip having an overhang region protruding from one side of the uppermost first semiconductor chip and an overlapping region overlapping the uppermost first semiconductor chip, the second chip pads including a plurality of first bonding pads in the overhang region and a plurality of second bonding pads in the overlapping region;
a plurality of first conductive bumps respectively on the plurality of first bonding pads of the second semiconductor chip;
a plurality of second conductive bumps respectively on the plurality of second bonding pads of the second semiconductor chip, the plurality of second conductive bumps between the second semiconductor chip and the uppermost first semiconductor chip;
a plurality of vertical wires extending from the plurality of first conductive bumps to substrate pads of the package substrate, respectively; and
a molding member on the upper surface of the package substrate, the molding member covering the plurality of first semiconductor chips, the second semiconductor chip, and the plurality of vertical wires.

2. The semiconductor package of claim 1, wherein the plurality of first conductive bumps surround at least portions of upper portions of the vertical wires respectively.

3. The semiconductor package of claim 1, wherein
the uppermost first semiconductor chip includes a plurality of third bonding pads on the upper surface of a second overlapping region overlapping the second semiconductor chip, and
the plurality of second conductive bumps are respectively between the plurality of second bonding pads of the second semiconductor chip and the plurality of third bonding pads of the uppermost first semiconductor chip.

4. The semiconductor package of claim 1, further comprising:
adhesive films, wherein
the plurality of first semiconductor chips are connected to each other on the upper surface of the package substrate with the adhesive films.

5. The semiconductor package of claim 1, wherein
each of the plurality of vertical wires includes a wire body, a first bonding end portion, and a second bonding end portion,
the wire body extends in a vertical direction,
the first bonding end portion is at a first end portion of the wire body and bonded to a corresponding one of the substrate pads, and
the second bonding end portion is at a second end portion of the wire body and bonded to a corresponding one of the plurality of first conductive bumps.

6. The semiconductor package of claim 5, wherein each of the plurality of vertical wires includes copper (Cu), gold (Au), or aluminum (Al).

7. The semiconductor package of claim 5, wherein, in at least one of the plurality of vertical wires,
the wire body has a first diameter,
the first bonding end portion has a second diameter, and
the second diameter is greater than the first diameter.

8. The semiconductor package of claim 1, further comprising:
a plurality of bonding wires that electrically connect the first chip pads of the plurality of first semiconductor chips to first substrate pads of the package substrate.

9. The semiconductor package of claim 1, wherein
at least a portion of the molding member surrounds the plurality of second conductive bumps between the uppermost first semiconductor chip and the second semiconductor chip.

10. The semiconductor package of claim 1, further comprising:
a bonding wire that electrically connects one of the first chip pads of one of the plurality of first semiconductor chips to a first substrate pad of the package substrate, wherein
the bonding wire has a first height as a maximum height from the package substrate,
the second semiconductor chip has a second height from the package substrate, and
the second height is greater than the first height.

11. A semiconductor package, comprising:
a package substrate;
a plurality of first semiconductor chips sequentially stacked in a stepwise manner on the package substrate;
a second semiconductor chip on an uppermost first semiconductor chip among the plurality of first semiconductor chips, a first surface of the second semiconductor chip including second chip pads and facing the package substrate, the second semiconductor chip having an overhang region protruding from one side of the uppermost first semiconductor chip and an overlapping region overlapping the uppermost first semiconductor chip;
conductive bumps on the second chip pads of the second semiconductor chip, the conductive bumps including a plurality of first conductive bumps on the second chip pads in the overhang region of the second semiconductor chip and a plurality of second conductive bumps on the second chip pads in the overlapping region of the second semiconductor chip, the second semiconductor chip being mounted on the uppermost first semiconductor chip using the second conductive bumps on the second chip pads in the overlapping region of the second semiconductor chip;
a plurality of bonding wires electrically connecting first chip pads of the plurality of first semiconductor chips to substrate pads of the package substrate;
a plurality of vertical wires respectively extending from the plurality of first conductive bumps on the second chip pads in the overhang region to the substrate pads of the package substrate; and
a molding member on the package substrate and covering the plurality of first semiconductor chips, the second semiconductor chip, the plurality of bonding wires, and the plurality of vertical wires.

12. The semiconductor package of claim 11, wherein
the second chip pads include a plurality of first bonding pads on a lower surface of the overhang region of the second semiconductor chip and a plurality of second bonding pads on a lower surface of the overlapping region of the second semiconductor chip, and
the plurality of first conductive bumps respectively on the plurality of first bonding pads and the second conductive bumps respectively on the plurality of second bonding pads.

13. The semiconductor package of claim 12, wherein the plurality of first conductive bumps surround at least portions of upper portions of the plurality of vertical wires respectively.

14. The semiconductor package of claim 12, wherein the plurality of second conductive bumps are between the second semiconductor chip and the uppermost first semiconductor chip.

15. The semiconductor package of claim 14, wherein
an upper surface of the uppermost first semiconductor chip includes a plurality of third bonding pads in a region of the uppermost first semiconductor chip that overlaps with the second semiconductor chip, and
the plurality of second conductive bumps are respectively between the plurality of second bonding pads of overlapping region of the second semiconductor chip and the plurality of third bonding pads of the uppermost first semiconductor chip.

16. The semiconductor package of claim 11, wherein
each of the plurality of vertical wires includes a wire body, a first bonding end portion, and a second bonding end portion,
the wire body extends in a vertical direction,
the first bonding end portion is at a first end portion of the wire body and bonded to a corresponding one of the substrate pads, and
the second bonding end portion is at a second end portion of the wire body and bonded to a corresponding one of the plurality of first conductive bumps.

17. The semiconductor package of claim 16, wherein at least one of the plurality of vertical wires includes copper (Cu), gold (Au), or aluminum (Al).

18. The semiconductor package of claim 16, wherein, in at least one of the plurality of vertical wires,
the wire body has a first diameter,
the first bonding end portion has a second diameter, and
the second diameter is greater than the first diameter.

19. The semiconductor package of claim 11, wherein the molding member surrounds the second conductive bumps between the uppermost first semiconductor chip and the second semiconductor chip.

20. (canceled)

21. A semiconductor package, comprising:
a package substrate having an upper surface and a lower surface, the lower surface of the package substrate being opposite the upper surface of the package substrate, the package substrate having a first side portion and a second side portion extending in a direction parallel to a first direction, the first side portion and the second side portion being opposite each other;
a plurality of first semiconductor chips sequentially attached on the upper surface of the package substrate, each of the plurality of first semiconductor chips including a first surface including first chip pads facing upward, and the plurality of first semiconductor chips being offset in a second direction, the second direction being perpendicular to the first direction;
a second semiconductor chip on an uppermost first semiconductor chip among the plurality of first semiconductor chips, the second semiconductor chip including a first surface including second chip pads facing downward, the second semiconductor chip being offset in the second direction, the second semiconductor chip having an overhang region protruding from one side of the uppermost first semiconductor chip and an overlapping region overlapping the uppermost first semiconductor chip, the second chip pads including a plurality of first bonding pads in the overhang region and a plurality of second bonding pads in the overlapping region;
a plurality of first conductive bumps respectively on the plurality of first bonding pads of the second semiconductor chip;
a plurality of second conductive bumps respectively on the plurality of second bonding pads of the second semiconductor chip, the plurality of second conductive bumps being between the second semiconductor chip and the uppermost first semiconductor chip;
a plurality of vertical wires extending from the plurality of first conductive bumps to substrate pads of the package substrate, respectively; and
a molding member on the upper surface of the package substrate, the molding member covering the plurality of first semiconductor chips, the second semiconductor chip, and the plurality of vertical wires.

22.-40. (canceled)
